(19) United States
(12) Patent Application Publication
(10) Pub. No.: US 2023/0243928 A1
(43) Pub. Date: Aug. 3, 2023

(54) OVERLAPPING SUB-RANGES WITH POWER STEPPING

(71) Applicant: Ouster, Inc., San Francisco, CA (US)

(72) Inventors: Tarek Al Abbas, Edinburgh (GB); Neil Calder, Edinburgh (GB); Robert Henderson, Edinburgh (GB)

(73) Assignee: Ouster, Inc., San Francisco, CA (US)

(21) Appl. No.: 18/102,940

(22) Filed: Jan. 30, 2023

Related U.S. Application Data
(60) Provisional application No. 63/304,678, filed on Jan. 30, 2022.
(60) Provisional application No. 63/417,624, filed on Oct. 19, 2022.

(51) Int. Cl. G01S 7/481; H01L 31/02; G01S 7/4863; G01S 7/4865; G01S 7/51

(52) U.S. Cl. CPC G01S 7/4811; H01L 31/02027; G01S 7/4863; G01S 7/4865; G01S 7/51

(57) ABSTRACT

Circuits, methods, and apparatus that can provide lidar systems having an increased dynamic range. One example can provide a lidar system having emitter elements to emit optical signals and sensor elements to detect incident photons. The emitter elements can emit a first optical signal having a series of pulses at a first power level and a second optical signal having a series of pulses at a second power level. Following first pulses, the sensor elements can determine a number of photons detected during a first number of time bins that begin with an initial time bin and extend to a first time bin. Following the second pulses, the sensor elements can determine a number of photons detected during a second number of time bins beginning with the initial time bin and extending to a second time bin. The second power level can differ from the first power level and the second number can differ from the first number.

### CROSS-REFERENCE TO RELATED APPLICATIONS

This application claims the benefit of U.S. application Nos. 63/304,678, filed Jan. 30, 2022, and 63/417,624, filed Oct. 19, 2022, which are incorporated by reference.

### BACKGROUND

This disclosure relates generally to lidar systems and more specifically increasing the dynamic range of lidar systems.

Time-of-flight (ToF) based imaging is used in a number of applications, including range finding, depth profiling, and 3D imaging, such as light imaging, detection, and ranging (LiDAR, or lidar). Direct time-of-flight (dToF) measurement includes directly measuring the length of time between emitting radiation from emitter elements and sensing the radiation by sensor elements after reflection from an object or other target. The distance to the target can be determined from the measured length of time. Indirect time-of-flight measurement includes determining the distance to the target by phase modulating the amplitude of the signals emitted by the emitter elements of the lidar system and measuring phases (e.g., with respect to delay or shift) of the echo signals received at the sensor elements of the lidar system. These phases can be measured with a series of separate measurements or samples.

In specific applications, the sensing of the reflected radiation in either direct or indirect time-of-flight systems can be performed using an array of detectors, such as an array of Single-Photon Avalanche Diodes (SPADs). One or more detectors can define a sensor for a pixel, where a sensor array can be used to generate a lidar image for the depth (range) to objects for respective pixels.

When imaging a scene, these sensors, which can also be referred to as ToF sensors or photosensors, can include circuits that time-stamp and count incident photons as reflected from a target. Data rates can be compressed by histogramming timestamps. For instance, for each pixel, a histogram having bins (also referred to as “time bins”) corresponding to different ranges of photon arrival times can be stored in memory, and photon counts can be accumulated in different time bins of the histogram according to their arrival time. A time bin can correspond to a duration of, e.g., 1 ns, 2 ns, or the like. Some lidar systems can perform in-pixel histogramming of incoming photons using a clock-driven architecture and a limited memory block, which can provide a significant increase in histogramming capacity. However, since memory capacity is limited and typically cannot cover the desired distance range at once, such lidar systems can operate in “strobing” mode. “Strobing” refers to the generation of detector control signals (also referred to herein as “strobe signals” or “strobes”) to control the timing and/or duration of activation (also referred to herein as “detection windows” or “strobe windows”) of one or more detectors of the lidar system, such that photon detection and histogramming is performed sequentially over a set of different time windows, each corresponding to an individual distance subrange, so as to collectively define the entire distance range. In other words, partial histograms can be acquired for subranges or “time slices” corresponding to different sub-ranges of the distance range and then amalgamated into one full-range histogram. Thousands of time bins (each corresponding to respective photon arrival times) can typically be used to form a histogram sufficient to cover the typical time range of a lidar system (e.g., microseconds) with the typical time-to-digital converter (TDC) resolution (e.g., 50 to 100 picoseconds).

Reflected light from the emitter elements can be received using a sensor array. The sensor array can be an array of SPADs for an array of pixels, also referred to as channels, where each pixel includes one or more SPADs to form one or more detector components. These SPADs can work in conjunction with other circuits, such as address generators, accumulation logic, memory circuits, and the like, to generate a lidar image.

It can be desirable for these lidar systems to be able to detect objects over a range of distances. For example, it can be desirable for these lidar systems to be able to detect objects that are close by as well as objects that are at a longer distance. As a result, it can be desirable that the lidar system have a large dynamic range to enable the detection of objects over a wide range of distances. Also, it can be desirable for these lidar systems to be able to determine a reflectivity of less reflective objects as well as highly reflective objects. As a result, it can also be desirable that the lidar system have a large dynamic range to enable the detection of objects over a range of reflectivity.

But it can be difficult to achieve a large dynamic range. For example, an intensity of light received by the sensor array can vary greatly. This light can be ambient light or light reflected from the emitter elements. Under some conditions, this light can provide enough photons to saturate SPADs in a sensor array. That is, SPADs in the sensor array can become saturated due to reflected and ambient light such that their corresponding bin counts can remain at or near a maximum level. When this saturation occurs, image information can be lost. To avoid saturation by reflected and ambient light, an f-stop of an aperture that allows light to reach the detector array can be increased. This increase in f-stop can block some light from reaching the SPADs in the sensor array and can help to reduce some SPAD saturation. Unfortunately, the increase in f-stop can also reduce light across the entire sensor array, thereby causing a loss of detail in darker portions of resulting lidar image.

Thus, what is needed are circuits, methods, and apparatus that can provide lidar systems having an increased dynamic range.

### SUMMARY

Accordingly, embodiments of the present invention can provide circuits, methods, and apparatus that can provide lidar systems having an increased dynamic range. An illustrative embodiment of the present invention can provide a lidar system having emitter elements that can emit optical signals at different power levels. The lidar system can further include sensor elements to detect incident photons. Control circuitry can be included to operate the plurality of emitter elements to emit a first optical signal having a number of pulses at a first power level. Following each pulse, the control circuit can further operate the sensor elements to determine a number of incident photons detected during a first number of time bins, the first number of time bins beginning with an initial time bin and extending to a final time bin. The control circuitry can further operate the plurality of emitter elements to emit a second optical signal having a series of pulses at a second power level. Following each pulse, the control circuit can further operate the sensor elements to determine a number of incident photons detected during the first number of time bins, the first number of time bins beginning with an initial time bin and extending to the final time bin. In these and other embodiments of the present invention, the second power level can be a higher power level than the first power level. In these and other embodiments of the present invention, the first power level can be a higher power level than the second power level. Different number of power levels can be used and their optical power levels can be varied in any order. For example, optical signals having an intermediate power level can be transmitted first, followed by optical signals having a lower power level, then optical signals having a higher power level. In this way, when time bins reach their maximum value and saturate following a higher-power optical signal, information can still be recovered from the corresponding time bins following a lower-power optical signal.

In these and other embodiments of the present invention, optical signals at two, three, four, five, or more than five power levels can be emitted by emitter elements and sensor elements can detect photons following each emitted optical signal. Optical signals at each power can be emitted for tens, hundreds, thousands, tens of thousands, or more than tens of thousands of pulses and corresponding cycles. Optical signals at different power levels can be emitted for different numbers of cycles. The resulting bin counts can be combined into a histogram, for example by adding or otherwise combining their values. Where different numbers of cycles are completed at different power levels, processing can be performed before or after the bin counts or values are combined. For example, a first algorithm can be performed on bin values stored following optical signals emitted at a first power level and a second algorithm can be performed on bin values stored following optical signals emitted at a second power level. These algorithms can be used to compensate for difference in background information, motion artifacts, or other factors. The results can then be added or otherwise combined in order to be used to generate a lidar image.

Another illustrative embodiment of the present invention can provide a lidar system having emitter elements that can emit optical signals at different power levels. The lidar system can further include sensor elements to detect incident photons. Control circuitry can be included to operate the plurality of emitter elements to emit a first optical signal having a number of pulses at a first power level. Following each pulse, the control circuit can further operate the sensor elements to determine a number of incident photons detected during a first number of time bins, the first number of time bins beginning with an initial time bin and extending to a first time bin. The control circuitry can further operate the plurality of emitter elements to emit a second optical signal having a number of pulses at a second power level. Following each pulse, the control circuit can further operate the sensor elements to determine a number of incident photons detected during a second number of time bins, the second number of time bins beginning with an initial time bin and extending to a second time bin. In these and other embodiments of the present invention, the second power level can be a higher power level than the first power level and the second number can be greater than the first number. In these and other embodiments of the present invention, the first power level can be a higher power level than the second power level and the first number can be greater than the second number. Different number of power levels can be employed and their optical power levels can be varied in any order. For example, optical signals having an intermediate power level can be transmitted first, followed by optical signals having a lower power level, then optical signals having a higher power level. In this way, when time bins reach their maximum value and saturate following a higher-power optical signal, information can still be recovered from the corresponding time bins following a lower-power optical signal.

The positions of the first time bin (where binning stops following emitted optical pulses at the first power level), the second time bin (where binning stops following emitted optical pulses at the second power level), and other such intermediate time bins can be fixed in hardware. Also or alternatively, the positions of these time bins can be programmable. Also or alternatively, some of these positions can be fixed while others can be programmable. Also or alternatively, the positions of these time bins can be determined by intraframe, interframe, inter-sub-frame, or intra-sub-frame results. For example, binning can continue beyond the first time bin following emitted signals at the first power level depending on results accumulated for either a current or previous histogram. This can also apply to binning following emitted optical pulses at various attenuated power levels.

In these and other embodiments of the present invention, optical signals at two, three, four, five, or more than five power levels can be emitted by emitter elements and sensor elements can detect photons following each emitted optical pulse. Following each optical signal at a specific power level, the control circuit can further operate the sensor elements to determine a number of incident photons detected during a corresponding number of time bins, the second number of time bins beginning with an initial time bin and extending to a corresponding time bin. Optical signals at each power can be emitted for tens, hundreds, thousands, tens of thousands, or more than tens of thousands of cycles. Optical signals at different power levels can be emitted for different numbers of cycles. The resulting bin counts can be combined into a histogram, for example by adding or otherwise combining their values. Where different numbers of cycles are completed at different power levels, processing can be performed before or after the bin values are combined. For example, a first algorithm can be performed on bin values stored following optical signals emitted at a first power level and a second algorithm can be performed on bin values stored following optical signals emitted at a second power level. These algorithms can be used to compensate for difference in background information, motion artifacts, differences in numbers of time bins used, or other factors. The results can then be added or otherwise combined in order to be used to generate a lidar image.

Some embodiments described herein provide methods, systems, and devices including electronic circuits that provide a lidar system including one or more emitter elements (including one or more light emitting devices or lasers, such as surface- or edge-emitting laser diodes; generally referred to herein as emitters or emitter elements) that output optical signals (referred to herein as emitter signals) in response to emitter control signals, one or more detector elements or sensor elements (including photodetectors, such as photodiodes, including avalanche photodiodes and single-photon avalanche detectors; generally referred to herein as detectors) that output detection signals in response to incident light (also referred to as detection events), and/or one or more control circuits that are configured to operate a non-transitory memory device to store data indicating the detection events in different subsets of memory banks during respective subframes of an imaging frame, where the respective subframes include data collected over multiple cycles or pulse repetitions of the emitter signals. For example, the one or more control circuits may be configured to operate the emitter and detector elements to collect data over fewer pulse repetitions of the emitter signal with smaller memory utilization (e.g., fewer memory banks) when imaging closer distance subranges, and to collect data over more pulse repetitions of the emitter signal with larger memory utilization (e.g., more memory banks) when imaging farther distance subranges.

In some embodiments, the control circuit(s) include a timing circuit that is configured to direct photon counts to a first subset of the memory banks based on their times-of-arrival with respect to the timing of the emitter signal during a first subframe, and to a second subset of the memory banks based on their times-of-arrival with respect to the timing of the emitter signal during a second subframe, thereby varying the number of memory banks and/or the time bin allocation of each memory bank or storage location for respective subframes of the imaging frame.

According to some embodiments of the present invention, a lidar detector circuit includes a plurality of detector pixels, with each detector pixel of the plurality comprising one or more detector elements; a non-transitory memory device comprising respective memory storage locations or memory banks configured to store photon count data for respective time bins or photon times-of arrival; and at least one control circuit configured to vary or change the number of memory banks and/or the allocation of respective time bins to the respective memory banks responsive to a number of pulse repetitions of an emitter signal. The at least one control circuit may be configured to change the respective time bins allocated to the respective banks from one subframe to the next by altering the timing of respective memory bank enable signals relative to the time between pulses of the emitter signal for the respective subframes. In some embodiments, the time bins of the respective subframes may have a same duration or bin width.

Various detector components formed of one or more SPADs can be implemented in these and other embodiments of the present invention. These detector components can be formed as arrays of individual SPADs, where the individual SPADs are connected together in different numbers to provide a number of detector components having different sensitivities.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 is a simplified block diagram of a lidar system according to some embodiments;

FIG. 2 is a simplified block diagram of components of a time-of-flight measurement system or circuit according to some embodiments;

FIG. 3 illustrates the operation of a typical lidar system that can be improved by embodiments;

FIG. 4 shows a histogram according to embodiments of the present invention;

FIG. 5 shows the accumulation of a histogram over multiple pulse trains for a selected pixel according to embodiments of the present invention;

FIG. 6 illustrates an example of a pixel according to an embodiment of the present invention;

FIG. 7A and FIG. 7B illustrate a method of operating a lidar system according to an embodiment of the present invention;

FIG. 8 is a conceptual histogram generated according to an embodiment of the present invention;

FIG. 9 is a graph showing a normalized intensity as a function of normalized photon rate provided by an embodiment of the present invention;

FIG. 10A and FIG. 10B illustrate a method of operating a lidar system according to an embodiment of the present invention;

FIG. 11 is a conceptual histogram generated according to an embodiment of the present invention;

FIG. 12 through FIG. 18 are graphs illustrating the performance of lidar systems according to embodiments of the present invention;

FIG. 19 illustrates boundary artifacts that can be minimized and corrected by embodiments of the present invention;

FIG. 20A and FIG. 20B illustrate a method of operating a lidar system according to an embodiment of the present invention;

FIG. 21 is a conceptual histogram generated according to an embodiment of the present invention;

FIG. 22A and FIG. 22B illustrate a method of operating a lidar system according to an embodiment of the present invention;

FIG. 23 is a conceptual histogram generated according to an embodiment of the present invention;

FIG. 24A and FIG. 24B illustrate a method of operating a lidar system according to an embodiment of the present invention;

FIG. 25 is a conceptual histogram generated according to an embodiment of the present invention;

FIG. 26 illustrates a method of operating a lidar system according to an embodiment of the present invention;

FIG. 27 illustrates a method of operating a lidar system according to an embodiment of the present invention;

FIG. 28 illustrates a method of operating a lidar system according to an embodiment of the present invention;

FIG. 29 further illustrates the method of FIG. 26 through FIG. 28;

FIG. 30 through FIG. 34D illustrate memory control and usage according to an embodiment of the present invention;

FIG. 35A is an example of a SPAD, and FIG. 35B illustrates an example of detector components for a pixel;

FIG. 36A and FIG. 36B illustrate examples of detector components for pixels; and

FIG. 37 is a simplified illustration of an automobile in which multiple solid-state flash lidar sensors according to some embodiments are included at different locations along the vehicle.

### DETAILED DESCRIPTION

Embodiments of the present invention can provide circuits, methods, and apparatus that can provide lidar systems having an increased dynamic range. One example can provide a lidar system having emitter elements to emit optical signals and sensor elements to detect incident photons. The emitter elements can emit a first optical signal having a series of pulses at a first power level and a second optical signal having a series of pulses at a second power level. Following first pulses, the sensor elements can determine a number of photons detected during a first number of time bins that begin with an initial time bin and extend to a first time bin. Following the second pulses, the sensor elements can determine a number of photons detected during a second number of time bins beginning with the initial time bin and extending to a second time bin. The second power level can differ from the first power level and the second number can differ from the first number.

### 1. Example Lidar System

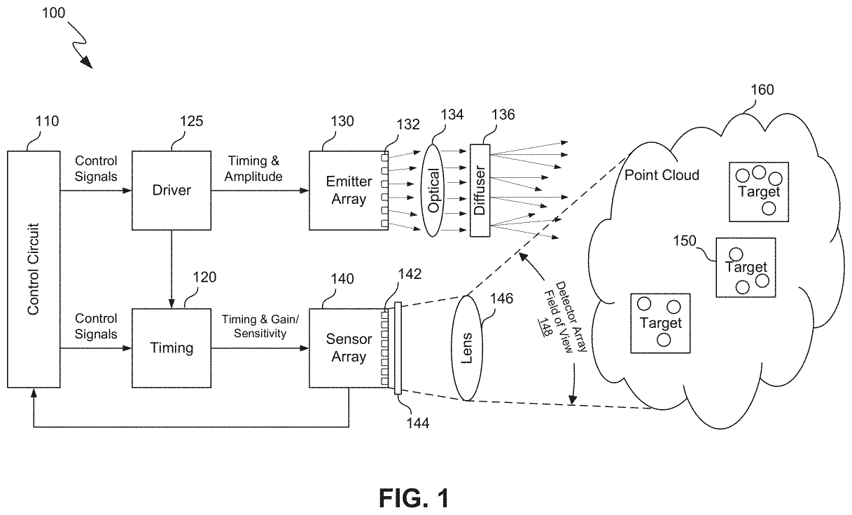

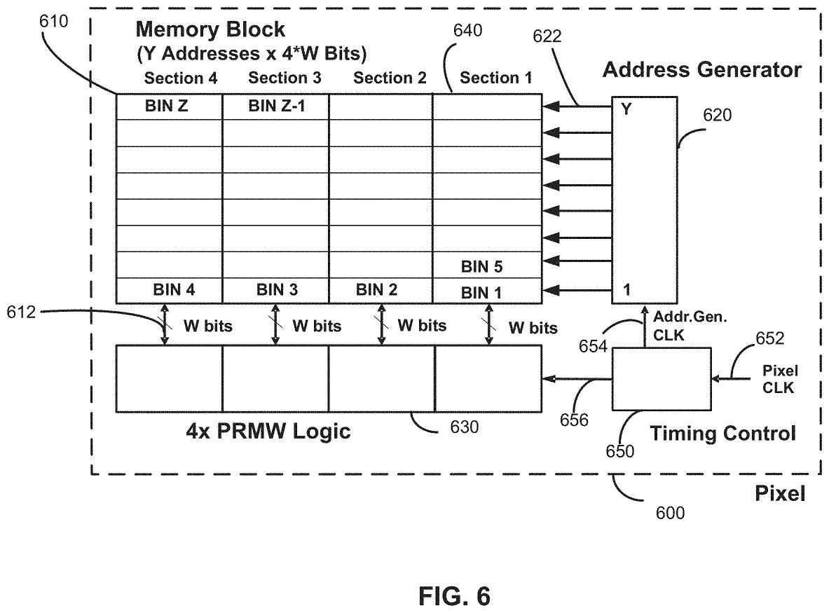

FIG. 1 illustrates an example light-based 3D sensor system 100, such as a Light Detection and Ranging (LiDAR, or lidar) system, in accordance with some embodiments of the invention. Lidar system 100 can include a control circuit 110, a timing circuit 120, driver circuitry 125, an emitter array 130 and a sensor array 140. Emitter array 130 can include a plurality of emitter units (or emitter elements) 132 arranged in an array (e.g., a one- or two-dimensional array) and sensor array 140 can include a plurality of sensors or sensor elements 142 arranged in an array (e.g., a one- or two-dimensional array). The sensors 142 can be depth sensors, such as time-of-flight (ToF) sensors. In some embodiments each sensor 142 can include, for example, one or more single-photon detectors, such as Single-Photon Avalanche Diodes (SPADs). In some embodiments, each sensor 142 can be coupled to an in-pixel memory block 610 (shown in FIG. 6) that accumulates histogram data for that sensor 142, and the combination of a sensor and in-pixel memory circuitry is sometimes referred to as a “pixel” 142. Each emitter unit 132 of the emitter array 130 can include one or more emitter elements that can emit a radiation pulse (e.g., light pulse) or continuous wave signal at a time and frequency controlled by a timing generator or driver circuitry 125. In some embodiments, the emitter units 132 can be pulsed light sources, such as LEDs or lasers such as vertical cavity surface emitting lasers (VCSELs) that emit a cone of light (e.g., infrared light) having a predetermined beam divergence.

Emitter array 130 can project pulses of radiation into a field of view of the lidar system 100. Some of the emitted radiation can then be reflected back from objects in the field, such as targets 150. The radiation that is reflected back can then be sensed or detected by the sensors 142 within the sensor array 140. Control circuit 110 can implement a processor that measures and/or calculates the distance to targets 150 based on data (e.g., histogram data) provided by sensors 142. In some embodiments control circuit 110 can measure and/or calculate the time of flight of the radiation pulses over the journey from emitter array 130 to target 150 and back to the sensors 142 within the sensor array 140 using direct or indirect time-of-flight (ToF) measurement techniques.

In some embodiments, emitter array 130 can include an array (e.g., a one- or two-dimensional array) of emitter units 132 where each emitter unit is a unique semiconductor chip having one or more individual VCSELs (sometimes referred to herein as emitter elements) formed on the chip. An optical element 134 and a diffuser 136 can be disposed in front of the emitter units such that light projected by the emitter units passes through the optical element 134 (which can include, e.g., one or more Fresnel lenses) and then through diffuser 136 prior to exiting lidar system 100. In some embodiments, optical element 134 can be an array of lenses or lenslets (in which case the optical element 134 is sometimes referred to herein as “lens array 134” or “lenslet array 134”) that collimate or reduce the angle of divergence of light received at the array and pass the altered light to diffuser 136. The diffuser 136 can be designed to spread light received at the diffuser over an area in the field that can be referred to as the field of view of the emitter array (or the field of illumination of the emitter array). In general, in these embodiments, emitter array 130, lens array or optical element 134, and diffuser 136 cooperate to spread light from emitter array 130 across the entire field of view of the emitter array. A variety of emitters and optical components can be used.

The driver circuitry 125 can include one or more driver circuits, each of which controls one or more emitter units. The driver circuits can be operated responsive to timing control signals with reference to a master clock and/or power control signals that control the peak power and/or the repetition rate of the light output by the emitter units 132. In some embodiments, each of the emitter units 132 in the emitter array 130 is connected to and controlled by a separate circuit in driver circuitry 125. In other embodiments, a group of emitter units 132 in the emitter array 130 (e.g., emitter units 132 in spatial proximity to each other or in a common column of the emitter array), can be connected to a same circuit within driver circuitry 125. Driver circuitry 125 can include one or more driver transistors configured to control the modulation frequency, timing, and/or amplitude of the light (optical emission signals) output from the emitter units 132.

In some embodiments, a single event of emitting light from the multiple emitter units 132 can illuminate an entire image frame (or field of view); this is sometimes referred to as a “flash” lidar system. Other embodiments can include non-flash or scanning lidar systems, in which different emitter units 132 emit light pulses at different times, e.g., into different portions of the field of view. The maximum optical power output of the emitter units 132 can be selected to generate a signal-to-noise ratio of the echo signal from the farthest, least reflective target at the brightest background illumination conditions that can be detected in accordance with embodiments described herein. In some embodiments, an optical filter (not shown) such as a bandpass filter can be included in the optical path of the emitter units 132 to control the emitted wavelengths of light.

Light output from the emitter units 132 can impinge on and be reflected back to lidar system 100 by one or more targets 150 in the field. The reflected light can be detected as an optical signal (also referred to herein as a return signal, echo signal, or echo) by one or more of the sensors 142 (e.g., after being collected by receiver optics 146), converted into an electrical signal representation (sometimes referred to herein as a detection signal), and processed (e.g., based on time-of-flight techniques) to define a 3-D point cloud representation 160 of a field of view 148 of the sensor array 140. In some embodiments, operations of lidar systems can be performed by one or more processors or controllers, such as control circuit 110.

Sensor array 140 includes an array of sensors 142. In some embodiments, each sensor 142 can include one or more photodetectors, e.g., SPADs. And in some particular embodiments, sensor array 140 can be a very large array made up of hundreds of thousands or even millions of densely packed SPADs. Receiver optics 146 and receiver electronics (including timing circuit 120) can be coupled to the sensor array 140 to power, enable, and disable all or parts of the sensor array 140 and to provide timing signals thereto. In some embodiments, sensors 142 can be activated or deactivated with at least nanosecond precision (supporting time bins of 1 ns, 2 ns, etc.), and in various embodiments, sensors 142 can be individually addressable, addressable by group, and/or globally addressable. The receiver optics 146 can include a bulk optic lens that is configured to collect light from the largest field of view that can be imaged by the lidar system 100, which in some embodiments is determined by the aspect ratio of the sensor array 140 combined with the focal length of the receiver optics 146.

In some embodiments, the receiver optics 146 can further include various lenses (not shown) to improve the collection efficiency of the sensors and/or an anti-reflective coating (also not shown) to reduce or prevent detection of stray light. In some embodiments, a spectral filter 144 can be positioned in front of the sensor array 140 to pass or allow passage of “signal” light (i.e., light of wavelengths corresponding to wavelengths of the light emitted from the emitter units) but substantially reject or prevent passage of non-signal light (i.e., light of wavelengths different from the wavelengths of the light emitted from the emitter units).

The sensors 142 of sensor array 140 are connected to the timing circuit 120. The timing circuit 120 can be phase-locked to the driver circuitry 125 of emitter array 130. The sensitivity of each of the sensor elements 142 or of groups of sensors 142 can be controlled. For example, when the sensor elements 142 include reverse-biased photodiodes, avalanche photodiodes (APD), PIN diodes, and/or Geiger-mode avalanche diodes (e.g., SPADs), the reverse bias can be adjusted. In some embodiments, a higher overbias provides higher sensitivity.

In some embodiments, control circuit 110, which can be, for example, a microcontroller or microprocessor, provides different emitter control signals to the driver circuitry 125 of different emitter units 132 and/or provides different signals (e.g., strobe signals) to the timing circuit 120 of different sensors 142 to enable/disable the different sensors 142 to detect the echo signal (or returning light) from the target 150. The control circuit 110 can also control memory storage operations for storing data indicated by the detection signals in a non-transitory memory or memory array that is included therein or is distinct therefrom.

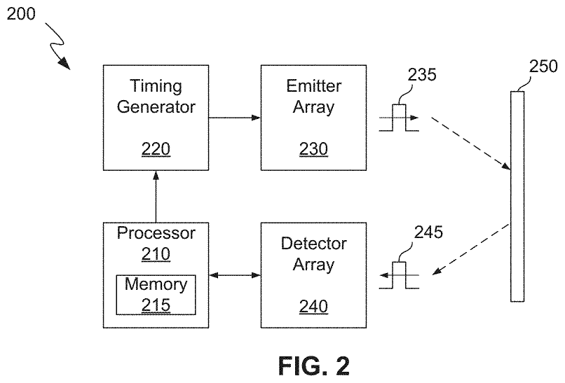

FIG. 2 further illustrates components of a ToF measurement system or circuit 200 in a lidar application in accordance with some embodiments described herein. The circuit 200 can include a processor circuit 210 (such as a digital signal processor (DSP)), a timing generator 220 that controls timing of the illumination source (illustrated by way of example with reference to a laser emitter array 230), and an array of sensors (illustrated by way of example with reference to a sensor array 240). The processor circuit 210 can also include a sequencer circuit (not shown in FIG. 2) that is configured to coordinate operation of emitter units within the illumination source (emitter array 230) and sensors within the sensor array 240.

The processor circuit 210 and the timing generator 220 can implement some of the operations of the control circuit 110 and the driver circuitry 125 of FIG. 1. Similarly, emitter array 230 and sensor array 240 can be representative of emitter array 130 and sensor array 140 in FIG. 1. The laser emitter array 230 can emit laser pulses 235 at times controlled by the timing generator 220. Light 245 from the laser pulses 235 can be reflected back from a target (illustrated by way of example as object 250) and can be sensed by sensor array 240. The processor circuit 210 implements a pixel processor that can measure or calculate the time of flight of each laser pulse 235 and its reflected light 245 over the journey from emitter array 230 to object 250 and back to the sensor array 240.

The processor circuit 210 can provide analog and/or digital implementations of logic circuits that provide the necessary timing signals (such as quenching and gating or strobe signals) to control operation of the single-photon detectors of the sensor array 240 and that process the detection signals output therefrom. For example, individual single-photon detectors of sensor array 240 can be operated such that they generate detection signals in response to incident photons only during the gating intervals or strobe windows that are defined by the strobe signals, while photons that are incident outside the strobe windows have no effect on the outputs of the single-photon detectors. More generally, the processor circuit 210 can include one or more circuits that are configured to generate detector or sensor control signals that control the timing and/or durations of activation of the sensors 142 (or particular single-photon detectors therein), and/or to generate respective emitter control signals that control the output of light from the emitter units 132.

Detection events can be identified by the processor circuit 210 based on one or more photon counts indicated by the detection signals output from the sensor array 240, which can be stored in a non-transitory memory 215. In some embodiments, the processor circuit 210 can include a correlation circuit or correlator that identifies detection events based on photon counts (referred to herein as correlated photon counts) from two or more single-photon detectors within a predefined window (time bin) of time relative to one another, referred to herein as a correlation window or correlation time, where the detection signals indicate arrival times of incident photons within the correlation window. Since photons corresponding to the optical signals output from the emitter array 230 (also referred to as signal photons) can arrive relatively close in time with each other, as compared to photons corresponding to ambient light (also referred to as background photons), the correlator can be configured to distinguish signal photons based on respective times of arrival being within the correlation time relative to one another. Such correlators and strobe windows are described, for example, in U.S. Patent Application Publication No. 2019/0250257, entitled “Methods and Systems for High-Resolution Long Range Flash Lidar,” which is incorporated by reference herein in its entirety for all purposes.

The processor circuit 210 can be small enough to allow for three-dimensionally stacked implementations, e.g., with the sensor array 240 “stacked” on top of processor circuit 210 (and other related circuits) that is sized to fit within an area or footprint of the sensor array 240. For example, some embodiments can implement the sensor array 240 on a first substrate, and transistor arrays of the processor circuit 210 on a second substrate, with the first and second substrates/wafers bonded in a stacked arrangement, as described for example in U.S. Patent Application Publication No. 2020/0135776, entitled “High Quantum Efficiency Geiger-Mode Avalanche Diodes Including High Sensitivity Photon Mixing Structures and Arrays Thereof,” the disclosure of which is incorporated by reference herein in its entirety for all purposes.

The pixel processor implemented by the processor circuit 210 can be configured to calculate an estimate of the average ToF aggregated over hundreds or thousands of laser pulses 235 and photon returns in reflected light 245. The processor circuit 210 can be configured to count incident photons in the reflected light 245 to identify detection events (e.g., based on one or more SPADs within the sensor array 240 that have been “triggered”) over a laser cycle (or portion thereof).

The timings and durations of the detection windows can be controlled by a strobe signal (Strobe #i or Strobe<i>). Many repetitions of Strobe #i can be aggregated (e.g., in the pixel) to define a sub-frame for Strobe #i, with subframes i=1 to n defining an image frame. Each sub-frame for Strobe #i can correspond to a respective distance sub-range of the overall imaging distance range. In a single-strobe system, a sub-frame for Strobe #1 can correspond to the overall imaging distance range and is the same as an image frame since there is a single strobe. The time between emitter unit pulses (which defines a laser cycle, or more generally emitter pulse frequency) can be selected to define or can otherwise correspond to the desired overall imaging distance range for the ToF measurement circuit 200. Accordingly, some embodiments described herein can utilize range strobing to activate and deactivate sensors for durations or “detection windows” of time over the laser cycle, at variable delays with respect to the firing of the laser, thus capturing reflected correlated signal photons corresponding to specific distance sub-ranges at each window/frame, e.g., to limit the number of ambient photons acquired in each laser cycle.

The strobing can turn off and on individual photodetectors or groups of photodetectors (e.g., for a pixel), e.g., to save energy during time intervals outside the detection window. For instance, a SPAD or other photodetector can be turned off during idle time, such as after an integration burst of time bins and before a next laser cycle. As another example, SPADs can also be turned off while all or part of a histogram is being read out from non-transitory memory 215. Yet another example is when a counter for a particular time bin reaches the maximum value (also referred to as “bin saturation”) for the allocated bits in the histogram stored in non-transitory memory 215. A control circuit can provide a strobe signal to activate a first subset of the sensors while leaving a second subset of the sensors inactive. In addition or alternatively, circuitry associated with a sensor can also be turned off and on as specified times.

### 2. Detection of Reflected Pulses

The sensors be arranged in a variety of ways for detecting reflected pulses. For example, the sensors can be arranged in an array, and each sensor can include an array of photodetectors (e.g., SPADs). A signal from a photodetector indicates when a photon was detected and potentially how many photons were detected. For example, a SPAD can be a semiconductor photodiode operated with a reverse bias voltage that generates an electric field of a sufficient magnitude that a single charge carrier introduced into the depletion layer of the device can cause a self-sustaining avalanche via impact ionization. The initiating charge carrier can be photo-electrically generated by a single incident photon striking the high field region. The avalanche is quenched by a quench circuit, either actively (e.g., by reducing the bias voltage) or passively (e.g., by using the voltage drop across a serially connected resistor), to allow the device to be “reset” to detect other photons. This single-photon detection mode of operation is often referred to as “Geiger Mode,” and an avalanche can produce a current pulse that results in a photon being counted. Other photodetectors can produce an analog signal (in real time) proportional to the number of photons detected. The signals from individual photodetectors can be combined to provide a signal from the sensor, which can be a digital signal. This signal can be used to generate histograms.

### 2.1. Time-of-Flight Measurements and Detectors

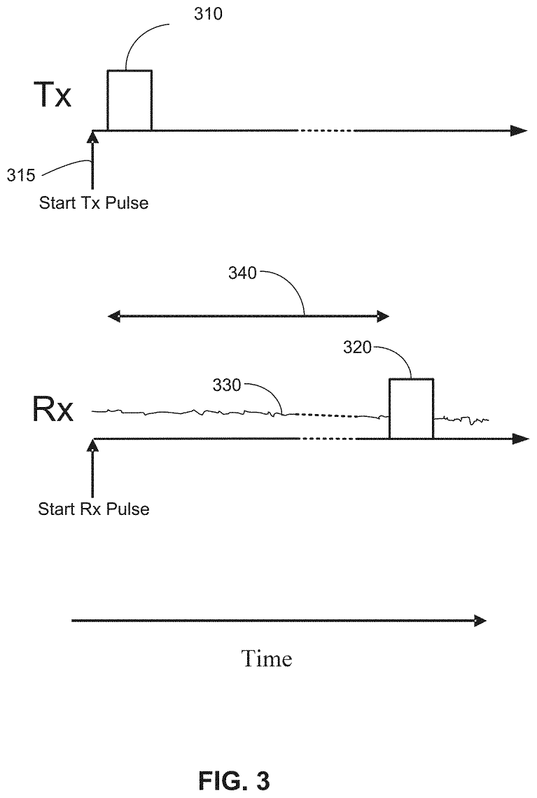

FIG. 3 illustrates the operation of a typical lidar system that can be improved by some embodiments. A laser or other emitter (e.g., within emitter array 230 or emitter array 130) generates a light pulse 310 of short duration. The horizontal axis represents time and the vertical axis represents power. An example laser pulse duration, characterized by the full-width half maximum (FWHM), is a few nanoseconds, with the peak power of a single emitter being around a few watts. Embodiments that use side emitter lasers or fiber lasers can have much higher peak powers, while embodiments with small diameter VCSELs could have peak powers in the tens of milliwatts to hundreds of milliwatts.

A start time 315 for the emission of the pulse does not need to coincide with the leading edge of the pulse. As shown, the leading edge of light pulse 310 can be after the start time 315. One can want the leading edge to differ in situations where different patterns of pulses are transmitted at different times, e.g., for coded pulses. In this example, a single pulse of light is emitted. In some embodiments, a sequence of multiple pulses can be emitted, and the term “pulse train” as used herein refers to either a single pulse or a sequence of pulses.

An optical receiver system (which can include, e.g., sensor array 240 or sensor array 140) can start detecting received light at the same time as the laser is started, i.e., at the start time. In other embodiments, the optical receiver system can start at a later time, which is at a known time after the start time for the pulse. The optical receiver system detects background light 330 initially and after some time detects the laser pulse reflection 320. The optical receiver system can compare the detected light intensity against a threshold to identify the laser pulse reflection 320. Where a sequence of pulses is emitted, the optical receiver system can detect each pulse. The threshold can distinguish the background light 330 from light corresponding to the laser pulse reflection 320.

The time-of-flight 340 is the time difference between the pulse 310 being emitted and the pulse reflection 320 being received. The time difference can be measured by subtracting the emission time of the pulse 310 (e.g., as measured relative to the start time) from a received time of the pulse reflection 320 (e.g., also measured relative to the start time). The distance to the target can be determined as half the product of the time-of-flight and the speed of light. Pulses from the laser device reflect from objects in the scene at different times, depending on start time and distance to the object, and the sensor array detects the pulses of reflected light.

2.2. Histogram Signals from Photodetectors

One mode of operation of a lidar system is time-correlated single photon counting (TCSPC), which is based on counting single photons in a periodic signal. This technique works well for low levels of periodic radiation which is suitable in a lidar system. This time correlated counting can be controlled by a periodic signal, e.g., from timing generator 220.

The frequency of the periodic signal can specify a time resolution within which data values of a signal are measured. For example, one measured value can be obtained for each photosensor per cycle of the periodic signal. In some embodiments, the measurement value can be the number of photodetectors that triggered during that cycle. The time period of the periodic signal corresponds to a time bin, with each cycle being a different time bin.

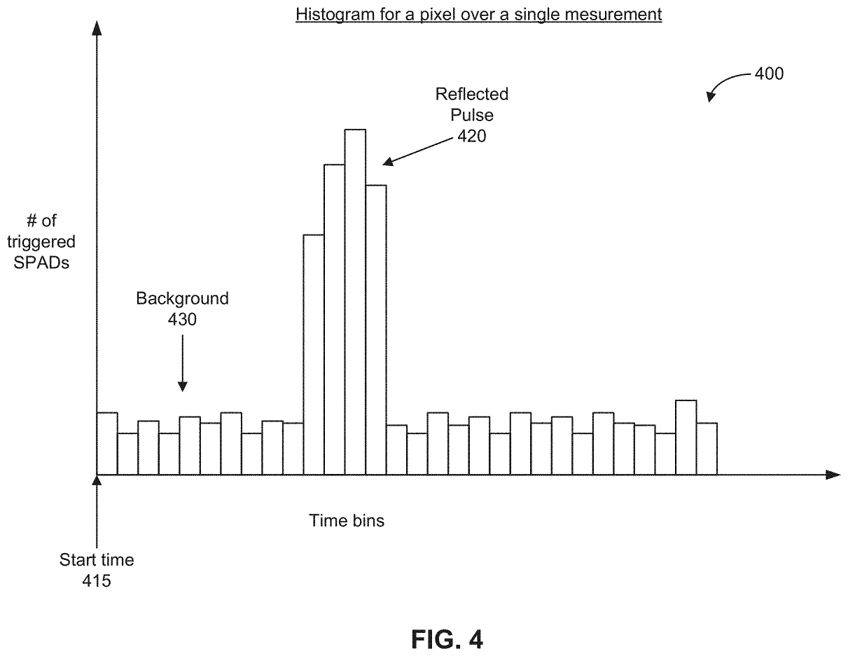

FIG. 4 shows a histogram 400 according to some embodiments described herein. The horizontal axis corresponds to time bins as measured relative to start time 415. As described above, start time 415 can correspond to a start time for an emitted pulse train. Any offsets between rising edges of the first pulse of a pulse train and the start time for either or both of a pulse train and a detection time interval can be accounted for when determining the received time to be used for the time-of-flight measurement. In this example, the sensor pixel includes a number of SPADs, and the vertical axis corresponds to the number of triggered SPADs for each time bin. Other types of photodetectors can also be used. For instance, in embodiments where APDs are used as photodetectors, the vertical axis can correspond to an output of an analog-to-digital converter (ADC) that receives the analog signal from an APD. It is noted that APDs and SPADS can both exhibit saturation effects. Where SPADs are used, a saturation effect can lead to dead time for the pixel (e.g., when all SPADs in the pixel are immediately triggered and no SPADs can respond to later-arriving photons). Where APDs are used, saturation can result in a constant maximum signal rather than the dead-time based effects of SPADs. Some effects can occur for both SPADs and APDs, e.g., pulse smearing of very oblique surfaces can occur for both SPADs and APDs.

The counts of triggered SPADs for each of the time bins correspond to the different bars in histogram 400. The counts at the early time bins are relatively low and correspond to background noise 430. At some point, a reflected pulse 420 is detected. The corresponding counts are much larger and can be above a threshold that discriminates between background and a detected pulse. The reflected pulse 420 results in increased counts in four time bins, which might result from a laser pulse of a similar width, e.g., a 4 ns pulse when time bins are each 1 ns.

The temporal location of the time bins corresponding to reflected pulse 420 can be used to determine the received time, e.g., relative to start time 415. In some embodiments, matched filters can be used to identify a pulse pattern, thereby effectively increasing the signal-to-noise ratio and allowing a more accurate determination of the received time. In some embodiments, the accuracy of determining a received time can be less than the time resolution of a single time bin. For instance, for a time bin of 1 ns, a resolution of one time bin would correspond to a distance about 15 cm. However, it can be desirable to have an accuracy of only a few centimeters.

Accordingly, a detected photon can result in a particular time bin of the histogram being incremented based on its time of arrival relative to a start signal, e.g., as indicated by start time 415. The start signal can be periodic such that multiple pulse trains are sent during a measurement. Each start signal can be synchronized to a laser pulse train, with multiple start signals causing multiple pulse trains to be transmitted over multiple laser cycles (also sometimes referred to as “shots”). Thus, a time bin (e.g., from 200 to 201 ns after the start signal) would occur for each detection interval. The histogram can accumulate the counts, with the count of a particular time bin corresponding to a sum of the measured data values all occurring in that particular time bin across multiple shots. When the detected photons are histogrammed based on such a technique, the result can be a return signal having a signal to noise ratio greater than that from a single pulse train by the square root of the number of shots taken.

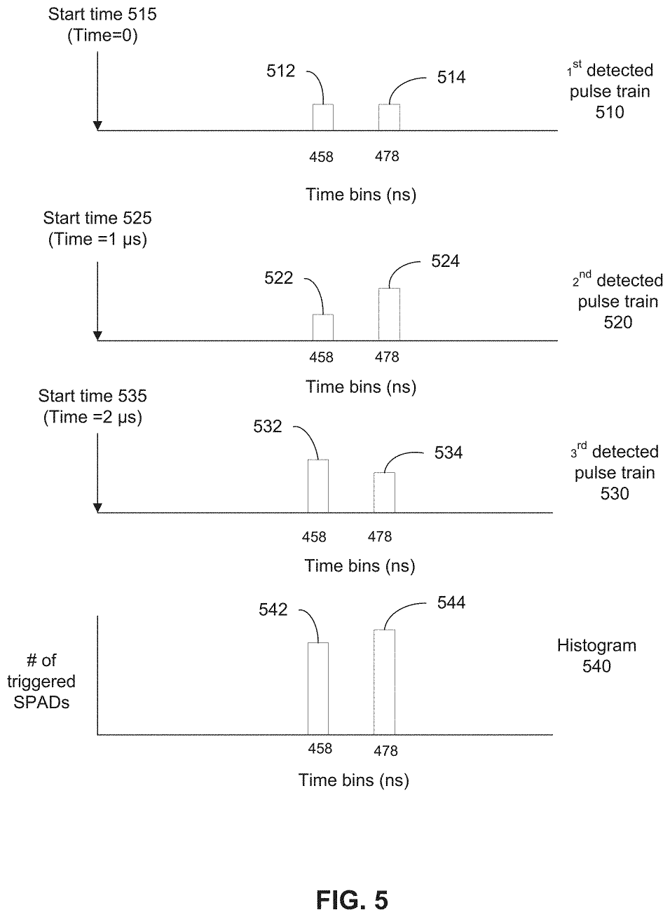

FIG. 5 shows the accumulation of a histogram over multiple pulse trains for a selected pixel according to some embodiments described herein. FIG. 5 shows three detected pulse trains 510, 520 and 530. Each detected pulse train corresponds to a transmitted pulse train that has a same pattern of two pulses separated by a same amount of time. Thus, each detected pulse train has a same pulse pattern, as shown by two time bins having an appreciable value. Counts for other time bins are not shown for simplicity of illustration, although the other time bins can have non-zero values (generally lower than the values in time bins corresponding to detected pulses).

In the first detected pulse train 510, the counts for time bins 512 and 514 are the same. This can result from a same (or approximately the same) number of photodetectors detecting a photon during each of the two time bins, or approximately the same number of photons being detected during the two time bins, depending on the particular photodetectors used. In other embodiments, more than one consecutive time bin can have a non-zero value; but for ease of illustration, individual nonzero time bins have been shown.

Time bins 512 and 514 respectively occur 458 ns and 478 ns after start time 515. The displayed counters for the other detected pulse trains occur at the same time bins relative to their respective start times. In this example, start time 515 is identified as occurring at time 0, but the actual time is arbitrary. The first detection interval for the first detected pulse train can be 1 μs. Thus, the number of time bins measured from start time 515 can be 1,000. After, this first detection interval ends, a new pulse train can be transmitted and detected. The start and end of the different time bins can be controlled by a clock signal, which can be part circuitry that acts as a time-to-digital converter (TDC).

For the second detected pulse train 520, the start time 525 is at 1 μs, at which time the second pulse train can be emitted. Time between start time 515 and start time 525 can be long enough that any pulses transmitted at the beginning of the first detection interval would have already been detected, and thus not cause confusion with pulses detected in the second detection interval. For example, if there is not extra time between shots, then the circuitry could confuse a retroreflective stop sign at 200 m with a much less reflective object at 50 m (assuming a shot period of about 1 us). The two detection time intervals for pulse trains 510 and 520 can be the same length and have the same relationship to the respective start time. Time bins 522 and 524 occur at the same relative times of 458 ns and 478 ns as time bins 512 and 514. Thus, when the accumulation step occurs, the corresponding counters can be added. For instance, the counter values at time bin 512 and 522 can be accumulated or added together.

For the third detected pulse train 530, the start time 535 is at 2 μs, at which time the third pulse train can be emitted. Time bin 532 and 534 also occur at 458 ns and 478 ns relative to start time 535. The counts for corresponding pulses of different pulse trains can have different values even though the emitted pulses have a same power, e.g., due to the stochastic nature of the scattering process of light pulses off of objects.

Histogram 540 shows an accumulation of the counts from three detected pulse trains 510, 520, 530 at time bins 542 and 544, which also correspond to 458 ns and 478 ns. Histogram 540 can have fewer time bins than were measured during the respective detection intervals, e.g., as a result of dropping time bins in the beginning or the end of the detection interval or time bins having values less than a threshold. In some implementations, about 10-30 time bins can have appreciable values, depending on the pattern for a pulse train.

As examples, the number of pulse trains emitted during a measurement to create a single histogram can be around 1-40 (e.g., 24), but can also be much higher, e.g., 50, 100, 500, or 1000. Once a measurement is completed, the counts for the histogram can be reset, and another set of pulse trains can be emitted to perform a new measurement. In various embodiments and depending on the number of detection intervals in the respective measurement cycles, measurements can be performed, e.g., every 25, 50, 100, or 500 μs. In some embodiments, measurement intervals can overlap, e.g., so that a given histogram corresponds to a particular sliding window of pulse trains. In such an example, memory can be provided for storing multiple histograms, each corresponding to a different time window. Any weights applied to the detected pulses can be the same for each histogram, or such weights could be independently controlled.

### 3. Pixel Operation

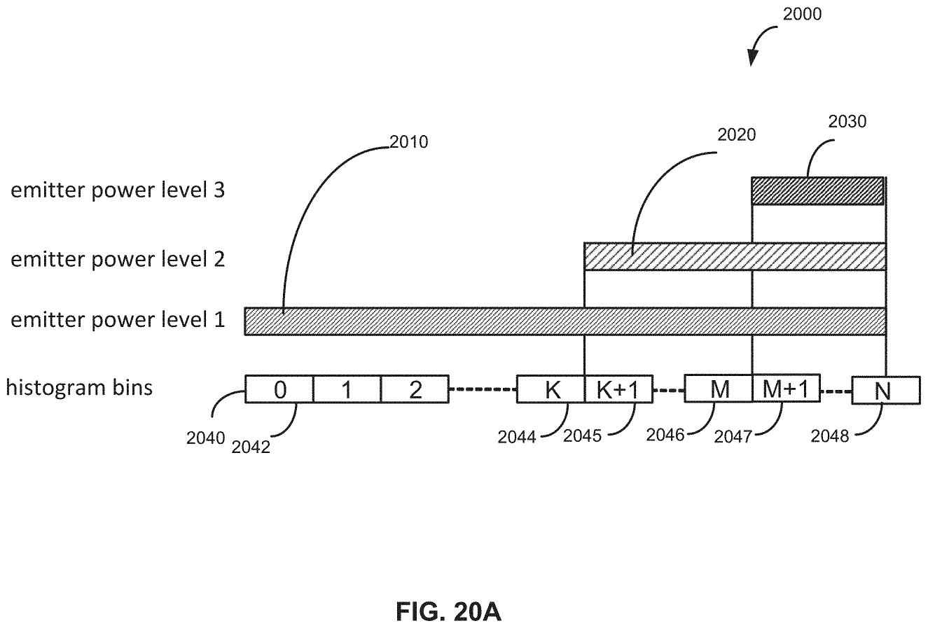

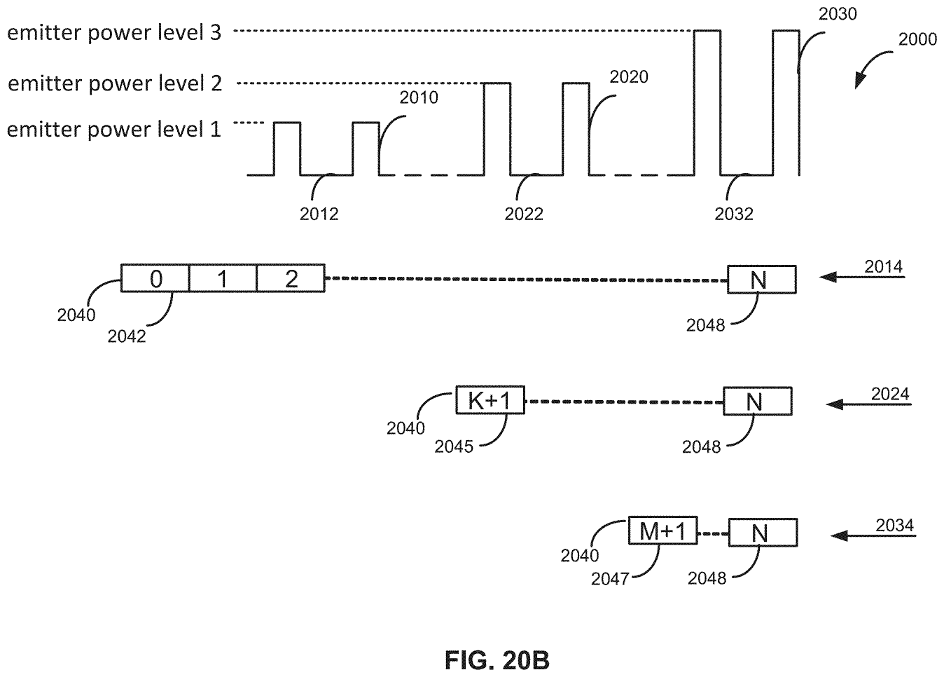

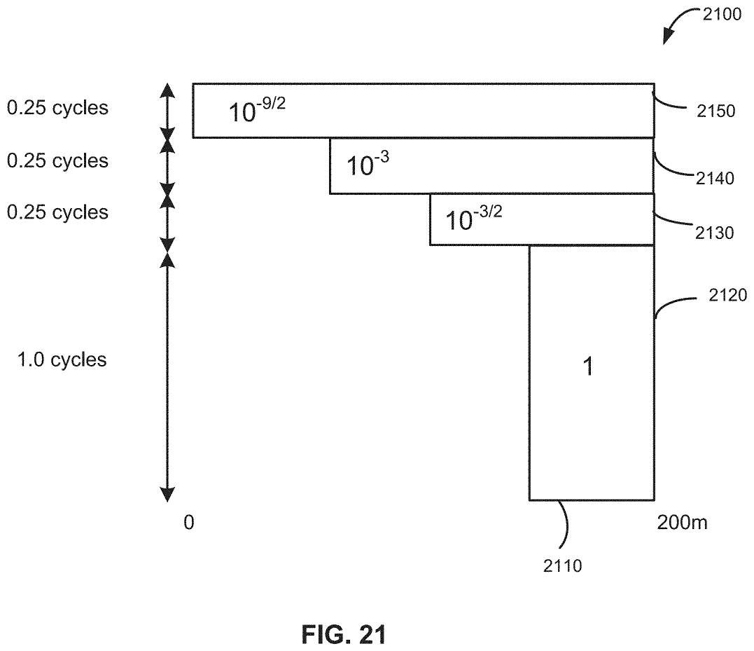

In some embodiments of the present invention, detector pixel 600, or more simply pixel 600, can include memory block 610, precharge-read-modify-write (PRMW) logic circuits 630, address generator 620, and timing control circuit 650 (all shown in FIG. 6.) Pixel 600 can include one or more photodetectors, such as the SPAD devices shown below in FIGS. 20 and 21, as well as other circuits or components (not shown.) Pixel 600 can be used as sensor 142 (shown in FIG. 1.)

FIG. 6 illustrates an example of a pixel according to an embodiment of the present invention. Pixel 600 can include an Y×4W memory block 610. Memory block 610 can include an array of memory cells arranged in Y rows and 4W columns, where the 4W columns are arranged as four memory banks 640 or sections, each having W memory cells. As shown in FIG. 6, timing control circuit 650 can receive a pixel clock on line 652. Timing control circuit 650 can provide an address generator clock on line 654 and pre-charge, read, modify, and write signals on lines 656 to PRMW logic circuits 630. Memory block 610 can be addressed using address generator 620 that provides Y row addresses on lines 622. Pixel 600 can include four PRMW logic circuits 630 of W bits each for a total of 4W bits, corresponding to the number of bitlines 612 or columns in memory block 610. In this configuration, four time bins can be stored in each row of memory block 610. In these and other embodiments of the present invention, Y can have a value of 32, 36, 40, 64, or other value, while W can have a value of 8, 10, 12, 16, or other value. Memory block 610 can be divided into two, three, five, or more than five sections with a corresponding number of PRMW logic circuits 630.

Pixels 600 can histogram events detected from one or more SPAD devices (shown in FIG. 21B) following an emitted pulse from emitter array 230 (shown in FIG. 2.) That is, the number of detected events from one or more SPAD devices can be time-sliced into time bins and accumulated in memory block 610. For example, the number of detected SPAD events from four preceding time bins can be stored in a temporary memory in the PRMW logic circuits 630 or other related circuit. Pixel 600 can perform a series of tasks, wherein during a first clock cycle, the PRMW logic circuits 630, under the control of timing control circuit 650, can perform a precharge task, where bitlines 612 for memory block 610 can be precharged. During a second clock cycle, the memory cells in the addressed row can be read by PRMW logic circuits 630. Bin counts stored in the addressed row can be modified by the PRMW logic circuits 630 by adding values from the temporary memory to the read value. The PRMW logic circuits 630 can then perform a write task to write the modified bin counts back to the memory cells for the four time bins in the addressed row in memory block 610. Further details of pixel 600 are described, for example, in U.S. Patent Application Publication No. 63/216,580, entitled “Highly Parallel Large Memory Histogramming Pixel for Direct Time of Flight Lidar,” the disclosure of which is incorporated by reference herein in its entirety for all purposes.

### 4. Using Power Stepping to Increase Dynamic Range

Again, it can be desirable for these lidar systems to be able to detect objects over a range of distances. For example, it can be desirable for these lidar systems to be able to detect objects that are close by as well as objects that are at a longer distance. Also, it can be desirable for these lidar systems to be able to detect objects having a low reflectivity as well as objects having a high reflectivity. As a result, it can be desirable that the lidar system have a large dynamic range to enable the detection of objects over a range of distances and a range of reflectivity.

But it can be difficult to achieve a large dynamic range. For example, an intensity of reflected light received by the sensor array can vary greatly. Under some conditions, this reflected light can provide enough photons to saturate SPADs in a sensor array. That is, SPADs in the sensor array can become saturated due to reflected light such that their corresponding bin counts can remain at or near a maximum level. When this saturation occurs, image information can be lost. To avoid saturation by reflected light, an f-stop of an aperture that allows light to reach the detector array can be increased. This increase in f-stop can block some light from reaching the SPADs in the sensor array and can help to reduce some SPAD saturation. Unfortunately, the increase in f-stop can also reduce reflected light across the entire sensor array, thereby causing a loss of detail in darker portions of resulting lidar image.

Accordingly, embodiments of the present invention can provide lidar systems having improved dynamic range. An example can have emitter elements that can provide optical signals over a range of optical power levels. This lidar system can further include detector elements that can detect incident photons. The detector elements can detect the presence of photons following an emitted optical pulse. The emitter elements can emit an optical signal having a first power level. Following this, circuitry for a pixel, such as pixel 600 (shown in FIG. 6) or other control or other circuitry, can determine a number of incident photons detected during a first number of time bins, the first number of time bins beginning with an initial time bin and extending to a final time bin. This can be repeated for tens, hundreds, thousands, or tens of thousands of cycles. The emitter elements can then emit an optical signal having a second power level. Following this, circuitry can determine a number of incident photons detected during the first number of time bins, the first number of time bins beginning with the initial time bin and extending to the final time bin. This can be repeated for tens, hundreds, thousands, or tens of thousands of cycles. The number of cycles at the first power level can be different than the number of cycles at the second power level. In this way, when time bins reach their maximum value and saturate following a higher-power optical signal, information can still be recovered from the corresponding time bins following a lower-power optical signal.

In these and other embodiments of the present invention, the second power level can be a higher power level than the first power level. In these and other embodiments of the present invention, the first power level can be a higher power level than the second power level. The optical power levels can be varied in any order and different numbers of power levels can be implemented. For example, optical signals having an intermediate power level can be transmitted first, followed by optical signals having a lower power level, then optical signals having a higher power level.

In these and other embodiments of the present invention, optical signals at two, three, four, five, or more than five power levels can be emitted by emitter elements and sensor elements can detect photons following each emitted optical signal. Optical signals at each power can be emitted for tens, hundreds, thousands, tens of thousands, or more than tens of thousands of cycles. Optical signals at different power levels can be emitted for different numbers of cycles. The resulting bin counts can be combined into a histogram, for example by adding or otherwise combining their values. Where different numbers of cycles are completed at different power levels, processing can be performed before or after the bin values are combined. For example, a first algorithm can be performed on bin values stored following optical signals emitted at a first power level and a second algorithm can be performed on bin values stored following optical signals emitted at a second power level. These algorithms can be used to compensate for difference in background information, motion artifacts, or other factors. The results can then be added or otherwise combined for use in generating a lidar image. An example is shown in the following figure.

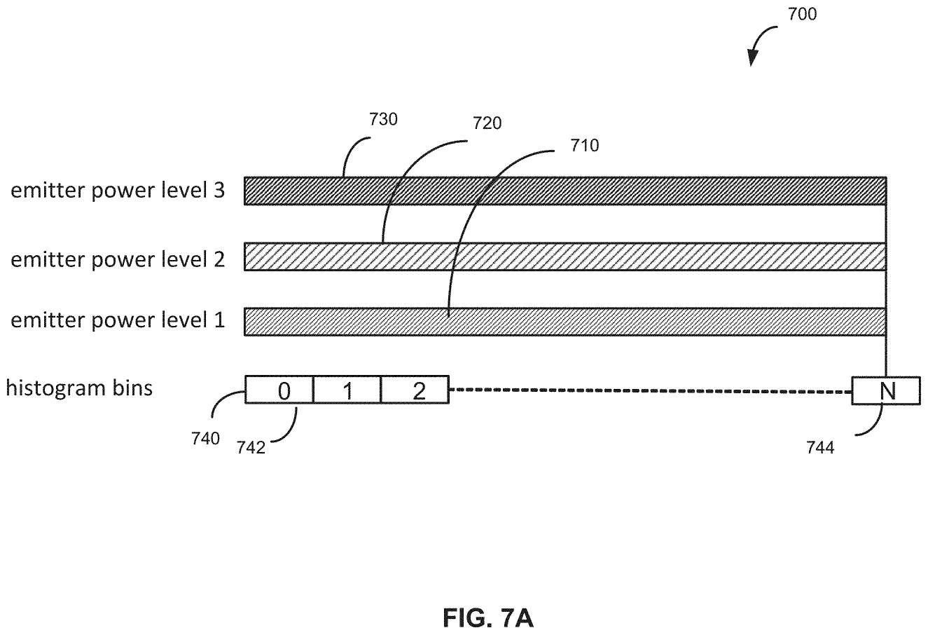

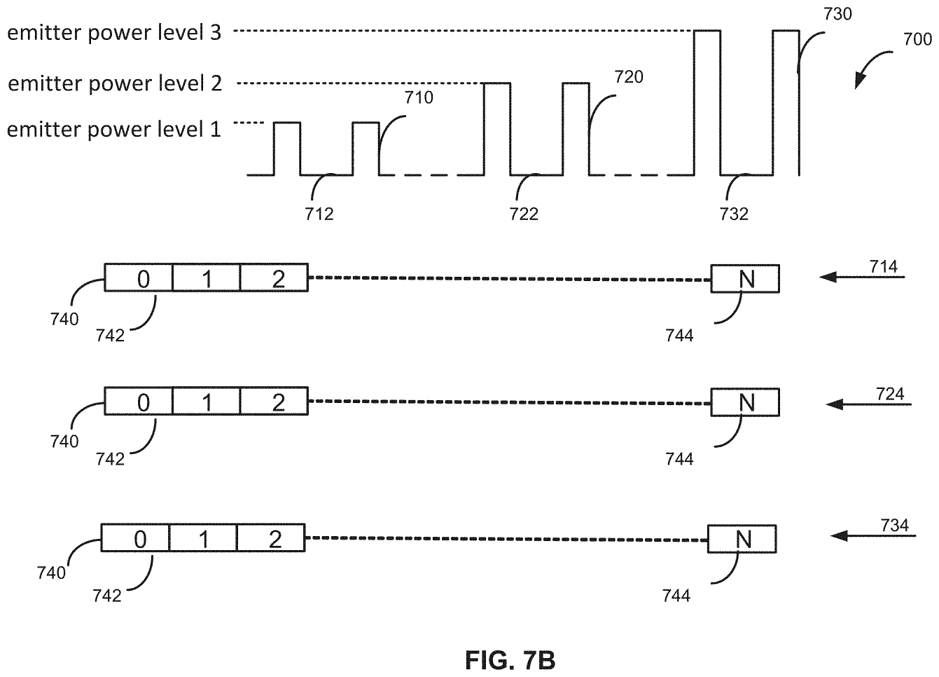

FIG. 7A illustrates a method of operating a lidar system according to an embodiment of the present invention. In this example 700, a first optical signal 710 having a series of pulses can be emitted by emitter elements 132 (shown in FIG. 1) and can have a first power level (emitter power level 1.) Following each pulse of first optical signal 710, sensor elements 142 (shown in FIG. 1) can detect photons during the time corresponding to time bins 740. This can be repeated for tens, hundreds, thousands, tens of thousands, or more pulses and corresponding cycles. Counts of detected photons can be accumulated in time bins 740, shown here as a sequence of time bins starting with an initial time bin 742 and ending with a final time bin 744. A second optical signal 720 having pulses with a second power level (emitter power level 2) can be emitted by emitter elements 132. Following each pulse of second optical signal 720, sensor elements 142 can detect photons during the time corresponding to time bins 740. Counts of detected photons can be accumulated in time bins 740 starting with the initial time bin 742 and ending with the final time bin 744. A third optical signal 730 having a series of pulses at a third power level (emitter power level 3) can be emitted by emitter elements 132. Following each pulse of third optical signal 730, sensor elements 142 can detect photons during the time corresponding to time bins 740. Counts of detected photons can be accumulated in time bins 740 starting with the initial time bin 742 and ending with the final time bin 744. The accumulated totals following the first optical signal 710, second optical signal 720, and third optical signal 730 can be added together or kept separate for post processing.

FIG. 7B illustrates the method of operating a lidar system according to FIG. 7A. In this example 700, a first optical signal 710 can be emitted by emitter elements 132 (shown in FIG. 1) and can include a series of pulses having a first power level (emitter power level 1.) Following each pulse, sensor elements 142 (shown in FIG. 1) can detect photons during time 712. There can be tens, hundreds, thousands, tens of thousands, or more pulses and corresponding cycles. Counts of detected photons can be accumulated as totals 714 in time bins 740, shown here as a sequence of time bins starting with an initial time bin 742 and ending with a final time bin 744. A second optical signal 720 having pulses at a second power level (emitter power level 2) can be emitted by emitter elements 132. Following each pulse, sensor elements 142 can detect photons during time 722. Counts of detected photons can be accumulated as totals 724 in time bins 740 starting with the initial time bin 742 and ending with the final time bin 744. A third optical signal 730 having a series of pulses at a third power level (emitter power level 3) can be emitted by emitter elements 132. Following each pulse, sensor elements 142 can detect photons during the time corresponding to time bins 740. Counts of detected photons can be accumulated as totals 734 in time bins 740 starting with the initial time bin 742 and ending with the final time bin 744. The accumulated totals 714, 724, and 734 can be added together or kept separate for postprocessing.

In this example, the third power level can be a higher power level than the second power level, which can be higher than the first power level. This order can be altered in any sequence. For example, the first power level can be a higher power level than the second power level, which can be higher than the third power level, the first power level can be a higher power level than the third power level, which can be higher than the second power level, or any other ranking can be employed.

Optical signals at the first power level can be emitted before optical signals at the second power level, which can be emitted before optical signals at the third power level. These optical signals can be emitted in different orders. For example, optical signals at the third power level can be emitted before optical signals at the second power level, which can be emitted before optical signals at the first power level, optical signals at the first power level can be emitted before optical signals at the third power level, which can be emitted before optical signals at the second power level, or any other sequence can be employed. The optical signals at the different levels can be interspersed or interleaved among each other. For example, some optical signals at the first power level can be emitted followed by some optical signals at the second power level and the third power level, followed by more optical signals at the first power level. This distribution can help to improve heat dissipation in the emitter array.

While three optical power levels are shown in this example, two, four, five, or more than five optical power levels can be used. An example is shown in the following figure.

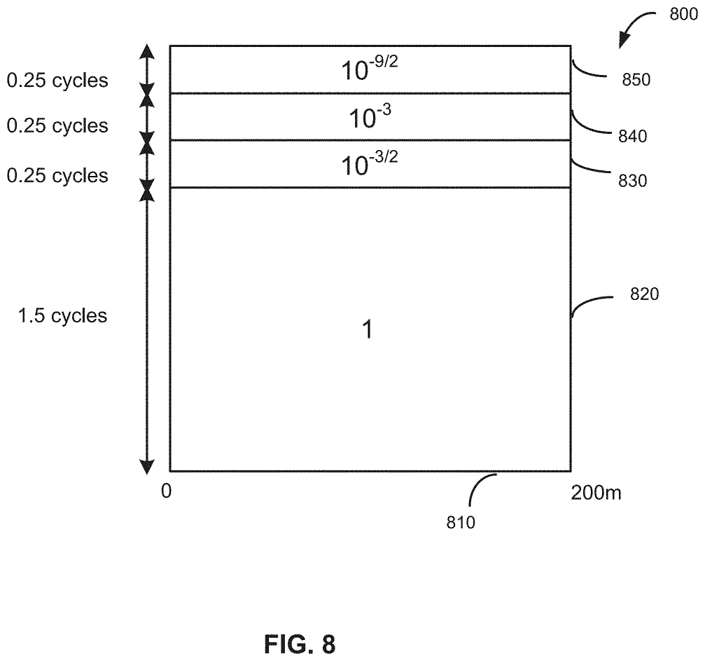

FIG. 8 is a conceptual histogram generated according to an embodiment of the present invention. In this example 800, a number of cycles 820 at a normalized optical power level of 1 are run and results are stored in time bins 810 corresponding to a distance of 200 meters, though other distances, such as 400 or 800 meters can be used. Optical signals at successively reduced power levels are emitted for cycles 830, 840, and 850. These cycles can utilize power levels successively reduced to normalized levels 10^{-3/2}, 10⁻³, and 10^{-9/2} as shown. The number of cycles can be one-quarter the nominal number of non-attenuated power level cycles, though in other embodiments of the present invention, other numbers of cycles can be run at each power level, and the numbers of cycles can be the same or different at each power level.

In these and other embodiments of the present invention, the number of cycles for each attenuated power level can be one-quarter the nominal number of non-attenuated power level cycles. The non-attenuated power level can require additional cycles to compensate for the increased integrated background. The number of additional cycles can be estimated using:

sqrt(N)=(N+K)/sqrt(N+K+M)

where N is the nominal number of cycles, M are the cycles of the attenuated levels and K is the additional required cycles. Simplifying for K,

K=N(sqrt(1+4(M/N))/2−1/2)

which for the considered case is 0.5 N. Accordingly, the normalized number of non-attenuated cycles can be 1 plus 0.5 or 1.5 normalized cycles. Again, there are a normalized number of attenuated power level cycles of 0.25. As a result, the total number of cycles can be estimated to have a normalized value of 2.25.

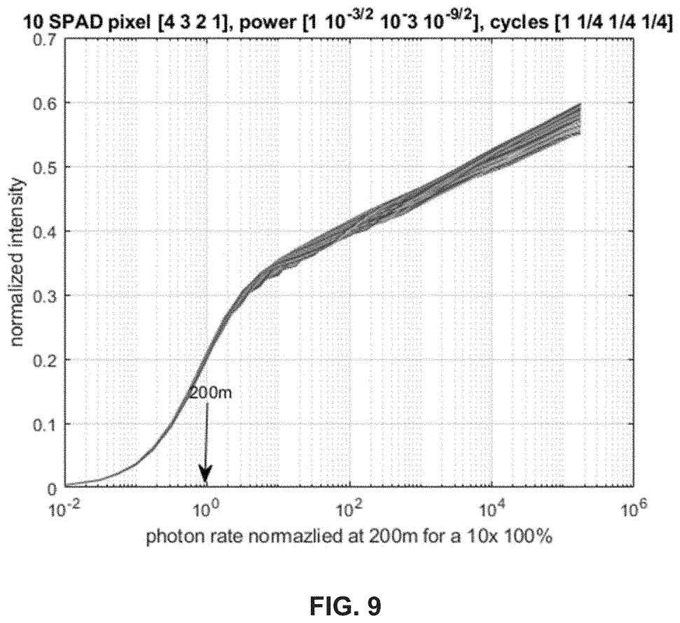

FIG. 9 is a graph showing a normalized intensity as a function of normalized photon rate provided by an embodiment of the present invention. In this example, the photon rate can be normalized at a distance of 200 meters for a 10×100 percent Lambertian surface.

### 5. Using Overlapping Sub-Ranges with Power Stepping to Increase Dynamic Range

In this example, photon detection data collected for long distances following lower power emitted optical signals might be of limited usefulness. Also, this data can increase photon counts from background or ambient light in the later time bins. Accordingly, the detection of photons for later time bins at lower power levels can be omitted. An example is shown in the following figure.

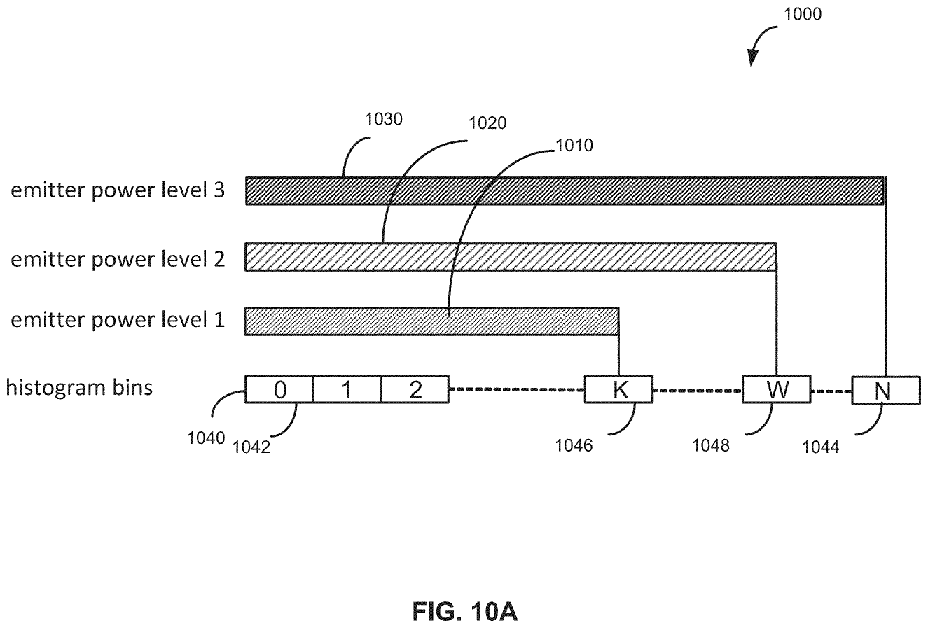

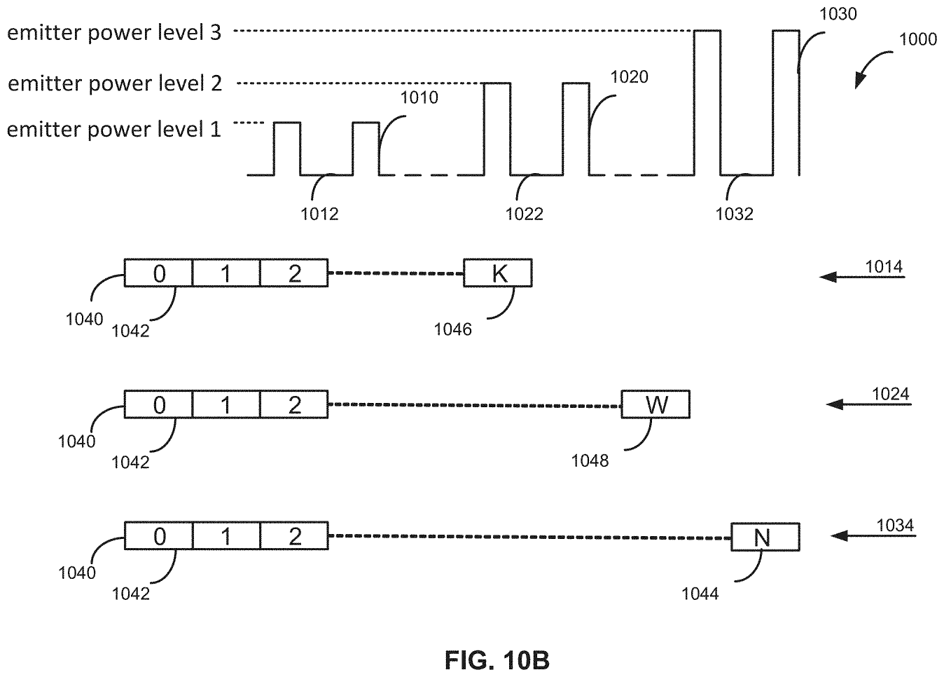

FIG. 10A illustrates a method of operating a lidar system according to an embodiment of the present invention. In this example, a first optical signal 1010 being emitted by emitter elements 132 (shown in FIG. 1) can have a series of pulses at a first power level (emitter power level 1.) Following each pulse, sensor elements 142 (shown in FIG. 1) can detect photons during the time corresponding to time bin 1042 through time bin K 1046. This can be repeated for tens, hundreds, thousands, tens of thousands, or more than tens of thousands of pulses and corresponding cycles. Counts of detected photons can be accumulated in some of the time bins 1040, shown here as a sequence of time bins starting with time bin 1042 and ending with time bin K 1046. A second optical signal 1020 having a series of pulses at a second power level (emitter power level 2) can be emitted by emitter elements 132. Following each pulse, sensor elements 142 can detect photons during the time corresponding to time bin 1042 through time bin W 1048. Again, this can be repeated for tens, hundreds, thousands, tens of thousands, or more than tens of thousands of pulses and corresponding cycles. Counts of detected photons can be accumulated in some of the time bins 1040, shown here as a sequence of time bins starting with the initial time bin 1042 and ending with a time bin W 1048. An optical signal 1030 having a third power level (emitter power level 3) can be emitted by emitter elements 132. Following each pulse, sensor elements 142 can detect photons during the time corresponding to time bin 1042 through time bin N 1044. Again, this can be repeated for tens, hundreds, thousands, tens of thousands, or more than tens of thousands of pulses and corresponding cycles. Counts of detected photons can be accumulated in the time bins 1040, shown here as a sequence of time bins starting with the initial time bin 1042 and ending with time bin N 1044. In this way, when time bins reach their maximum value and saturate following a higher-power optical signal, information can still be recovered from the corresponding time bins that follow the emission of a lower-power optical signal. The accumulated totals following the first optical signal 1010, second optical signal 1020, and third optical signal 1030 can be added together or kept separate for postprocessing.

FIG. 10B illustrates the method of operating a lidar system according to FIG. 10A. In this example 1000, a first optical signal 1010 can be emitted by emitter elements 132 (shown in FIG. 1) and can include a series of pulses having a first power level (emitter power level 1.) Following each pulse, sensor elements 142 (shown in FIG. 1) can detect photons during time 1012. There can be tens, hundreds, thousands, tens of thousands, or more pulses and corresponding cycles. Counts of detected photons can be accumulated as totals 1014 in time bins 1040, shown here as a sequence of time bins starting with an initial time bin 1042 and ending with time bin K 1046. A second optical signal 1020 having a second power level (emitter power level 2) can be emitted by emitter elements 132. Following each pulse, sensor elements 142 can detect photons during time 1022. Counts of detected photons can be accumulated as totals 1024 in time bins 1040 starting with the initial time bin 1042 and ending with the time bin W 1048. A third optical signal 1030 having a series of pulses at a third power level (emitter power level 3) can be emitted by emitter elements 132. Following each pulse, sensor elements 142 can detect photons during the time corresponding to time bins 1040. Counts of detected photons can be accumulated as totals 1034 in time bins 1040 starting with the initial time bin 1042 and ending with the final time bin 1044. The accumulated totals 1014, 1024, and 1034 can be added together or kept separate for postprocessing.

In this example, some histogram time bins are shown as not being written to. This might have minimal impact on a generated lidar image as the contribution to distant objects by lower power optical signals can be negligible. That is, following a low-power emitter pulse, photons detected at time bins corresponding to longer distances can have a very low signal-to-power ratio. Omitting this data can help to improve the overall signal-to-noise ratio of the final histogram totals. This reduction can reduce a required amount of memory in pixel 600 (shown in FIG. 6.) It can also decrease the time needed to generate each histogram. In this specific example, time bins after the time bin K 1046 to time bin N 1044 are not used following emitted optical pulses having the first optical power. Similarly, the time bins after the time bin W 1048 to the time bin N 1044 are not used following emitted optical pulses having the second optical power. This allows results measurements and binning to cease and a new cycle to begin earlier.

In these and other embodiments of the present invention, the positions of bin K 1046 (that is, the bin after which binning stops following emitted optical pulses at the first power level), bin W 1048 (that is, the bin after which binning stops following emitted optical pulses at the second power level), and other such intermediate bins, can be fixed in hardware. Also or alternatively, the positions of these bins can be programmable. Also or alternatively, the positions of these bins can be determined by intraframe, interframe, inter-sub-frame, or intra-sub-frame results. For example, binning can stop after or before time bin K 1046 following emitted signals at the first power level depending on results accumulated for either a current or previous histogram. Similar variations can be implemented following other attenuated optical signals. Also or alternatively, the positions of these bins can be determined by interactive software.

In these and other embodiments of the present invention, the bins shown as time bin K 1046, time bin W 1048, and other specific time bins can be fixed or otherwise positioned at predetermined locations in time bins 1040. In these and other embodiments of the present invention, the positions of time bin K 1046, time bin W 1048, and other specific time bins can be programmably or otherwise variably positioned in the range of time bins 1040. Limits can be placed on the positions of time bin K 1046 and time bin W 1048 to avoid the necessity of the inclusion of resources or processing that might have a limited utility.

In this example, the third power level can be a higher power level than the second power level, which can be higher than the first power level. This order can be altered in any sequence. For example, the first power level can be a higher power level than the second power level, which can be higher than the third power level, the first power level can be a higher power level than the third power level, which can be higher than the second power level, or any other ranking can be employed.

Optical signals at the first power level can be emitted before optical signals at the second power level, which can be emitted before optical signals at the third power level. These optical signals can be emitted in different orders. For example, optical signals at the third power level can be emitted before optical signals at the second power level, which can be emitted before optical signals at the first power level, optical signals at the first power level can be emitted before optical signals at the third power level, which can be emitted before optical signals at the second power level, or any other sequence can be employed. The optical signals at the different levels can be interspersed or interleaved among each other. For example, some optical signals at the first power level can be emitted followed by some optical signals at the second power level and the third power level, followed by more optical signals at the first power level. This distribution can help to improve heat dissipation in the emitter array.

While three optical power levels are shown in this example, two, four, five, or more than five optical power levels can be used. An example is shown in the following figure.

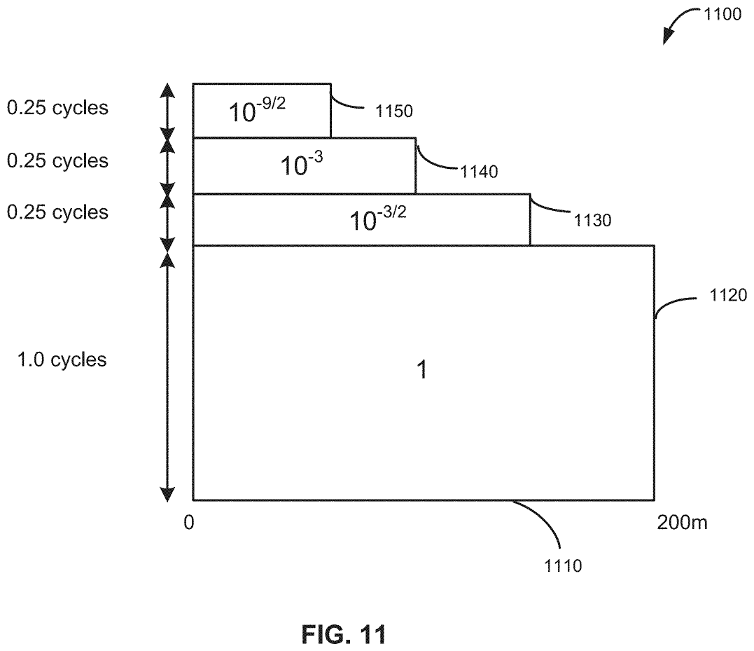

FIG. 11 is a conceptual histogram generated according to an embodiment of the present invention. In this example 1100, a number of cycles 1120 at a normalized optical power level of 1 are run and results are stored in time bins 1110 corresponding to a distance of 200 meters, though other distances, such as 400 or 800 meters can be used. Optical signals at successively reduced power levels are emitted for cycles 1130, 1140, and 1150 as shown. These cycles can utilize power levels successively reduced to normalized levels 10^{-3/2}, 10⁻³, and 10^{-9/2} as shown. The number of cycles can be one-quarter the nominal number of non-attenuated power level cycles, though in other embodiments of the present invention, other percentages of the nominal number of non-attenuated power level cycles can be used, and the numbers of cycles at each power level can be different. Detected photon data from the sensor elements 142 (shown in FIG. 1) are not binned for successively longer times following emitted optical signals having lower power. For example, detected photon data following emitted optical data signals at the normalized power level of 10^{-3/2} is binned for a shorter time (for a reduced number of time bins) than detected photon data following emitted optical data signals at the normalized power level of 1. Similarly, detected photon data following emitted optical data signals at the normalized power level of 10⁻³ is binned for a shorter time than detected photon data following emitted optical data signals at the normalized power level of 10^{-3/2}. Similarly, detected photon data following emitted optical data signals at the normalized power level of 10^{-9/2} is binned for a shorter time than detected photon data following emitted optical data signals at the normalized power level of 10⁻³.

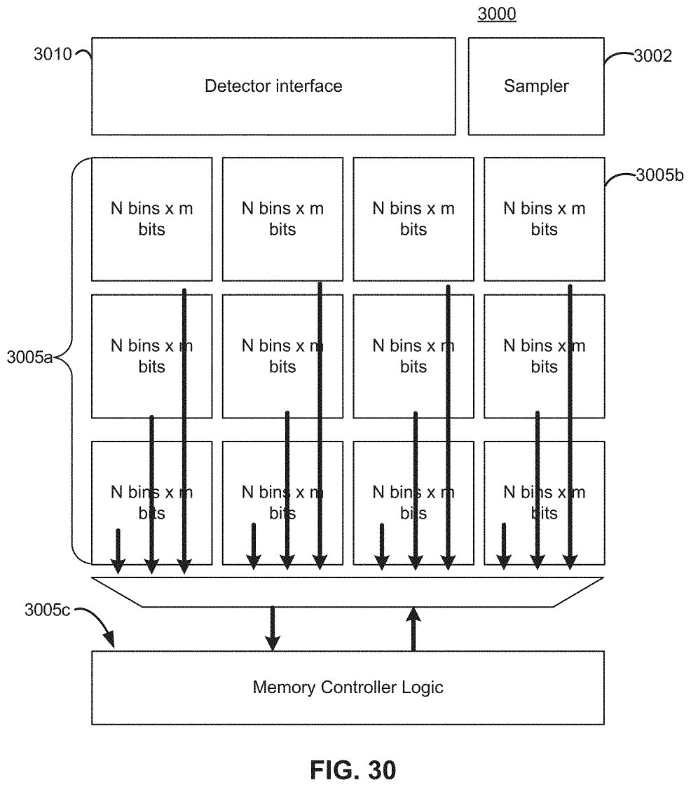

These and other embodiments can count detected photons for various number of cycles. In one example, a maximum count per time bin can be 16,000. A sensor for each pixel can employ four detector components, such as the detector components or sensor shown in FIG. 30B. In this example, the nominal number of cycles 1120 at an unattenuated power level, or a normalized power level of 1, can be 2,000. Cycles 1130, 1140, and 1150 can include 500 cycles. Each of these power levels can generate up to 2,000 counts each, or 6,000 counts total. The 2000 cycles of cycles 1120 can reach a count of four times that value, or 8000. Other numbers of cycles and other numbers of detector components can be utilized in this and other embodiments of the present invention. The numbers of cycles and numbers of detector components can be fixed, programmable, determined by interactive software, or otherwise set.

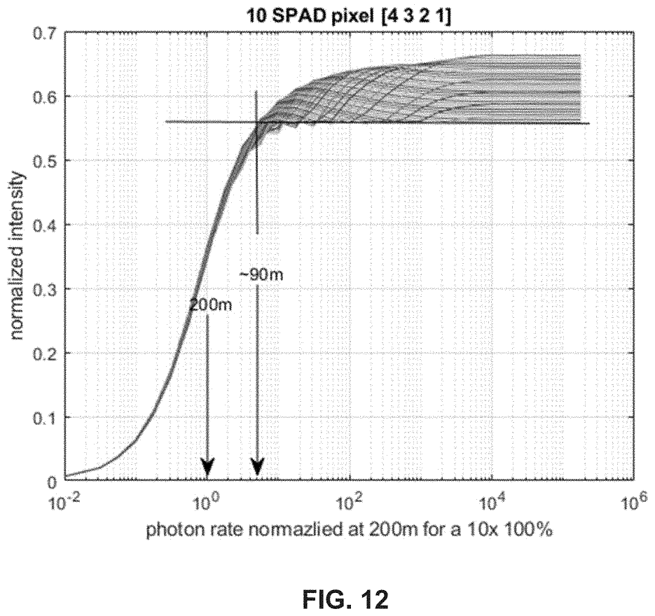

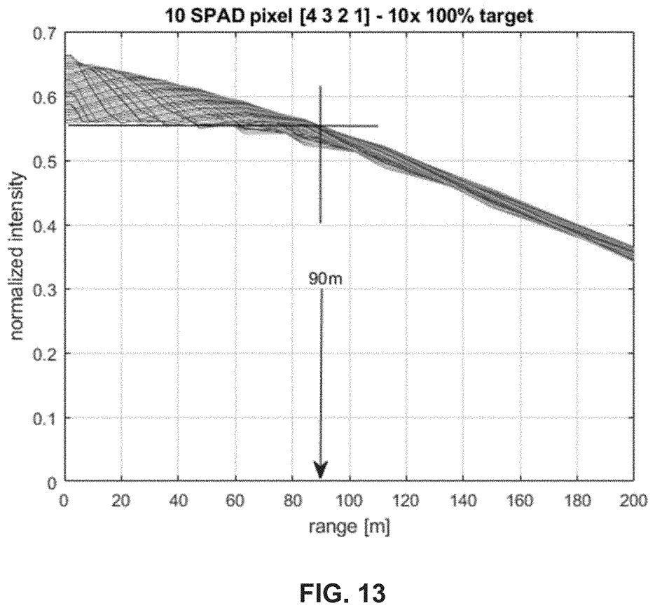

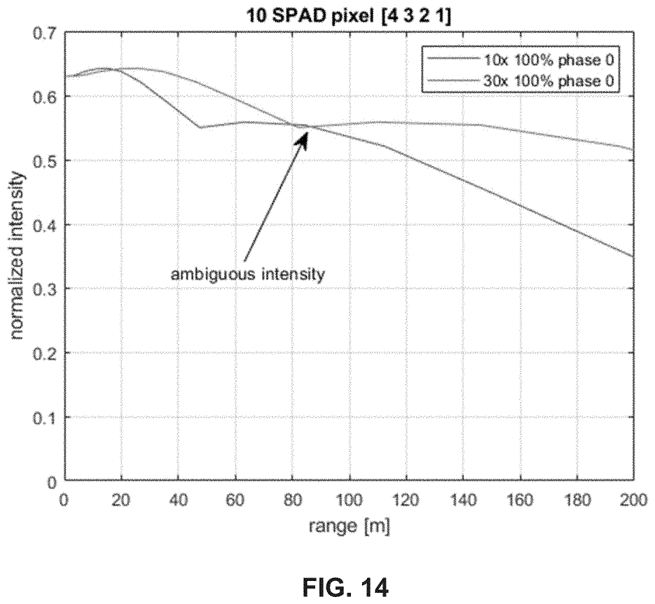

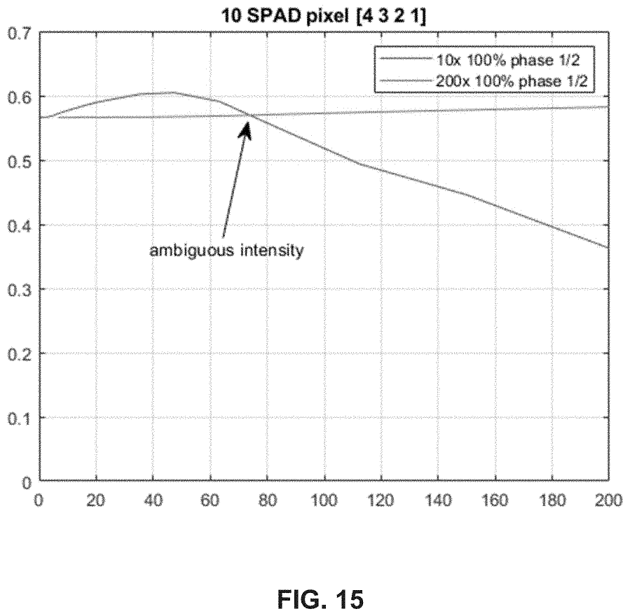

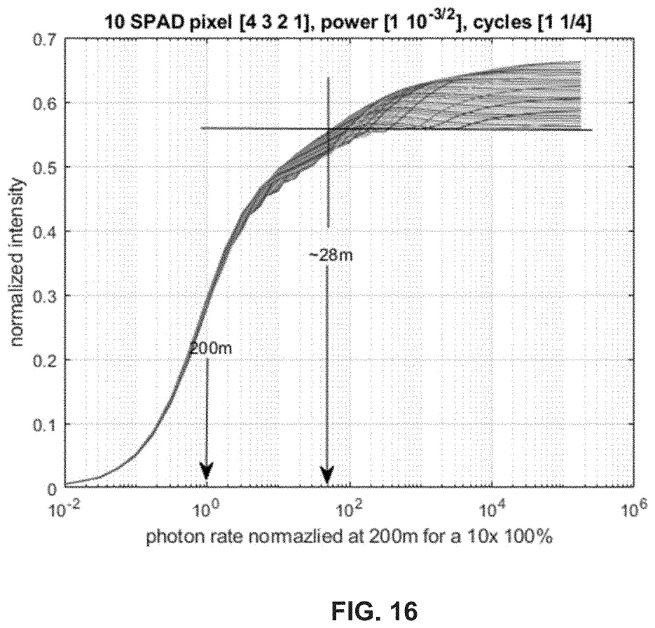

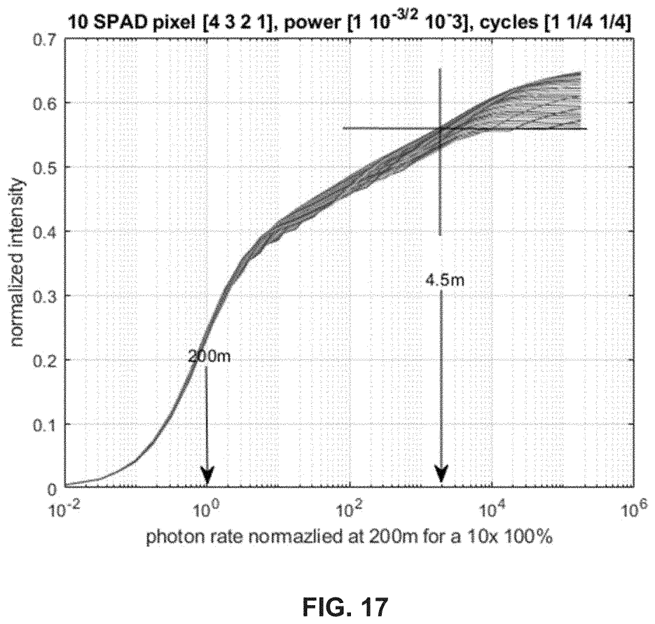

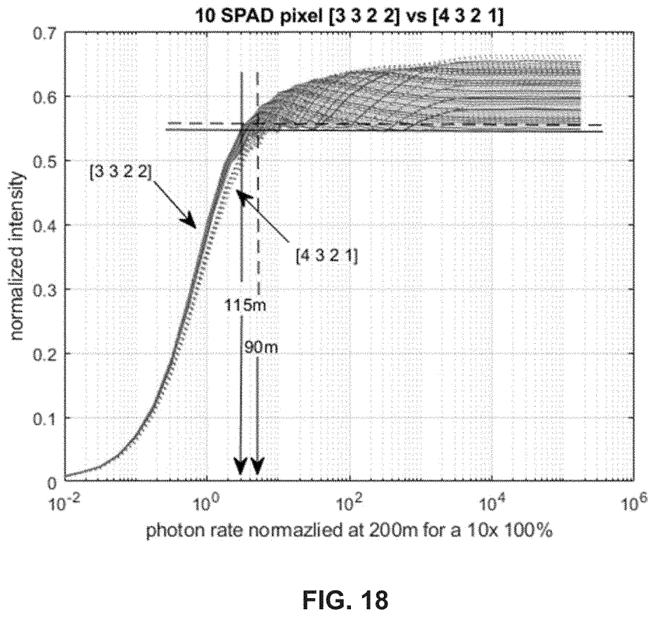

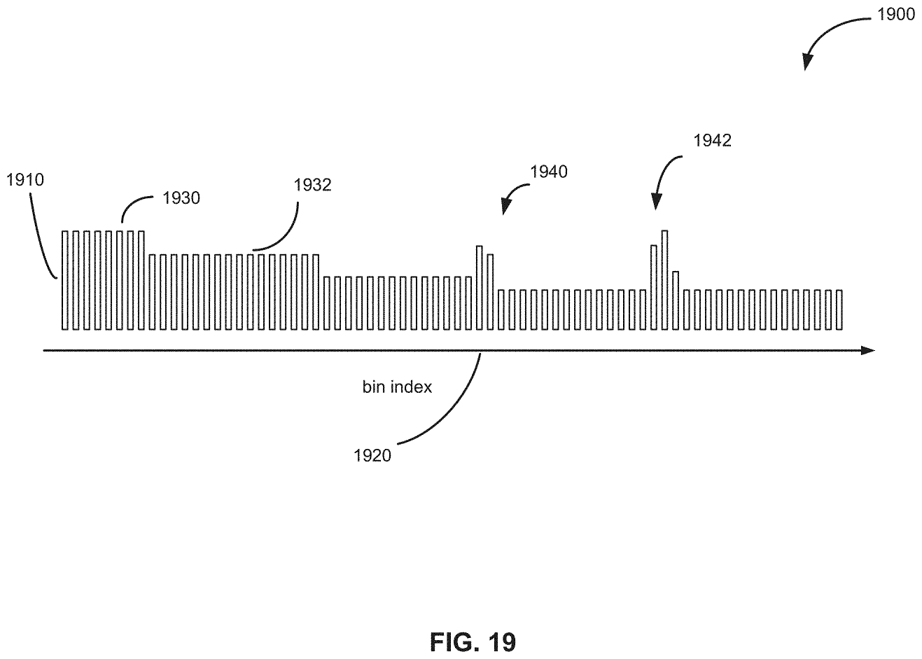

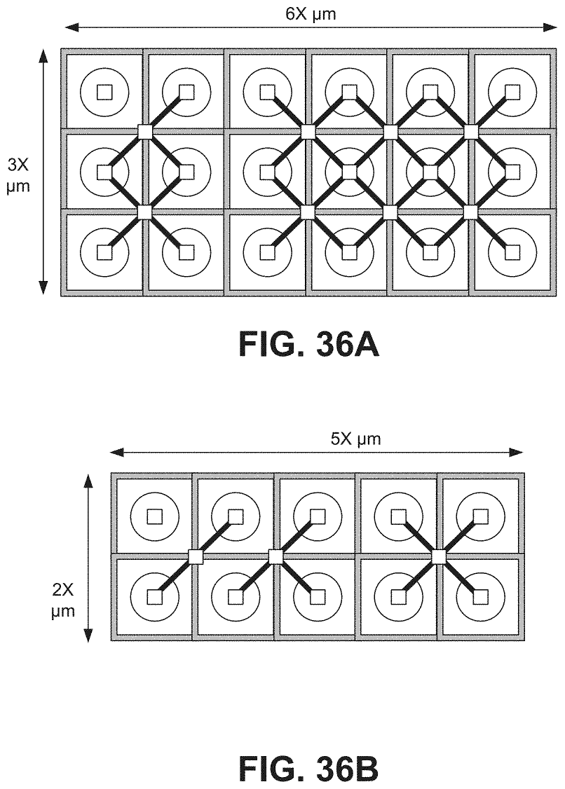

FIG. 12 through FIG. 18 are graphs illustrating the performance of lidar systems according to embodiments of the present invention. FIG. 12 shows signal saturation, and therefore loss of signal contrast, occurring at about 90 m. This distance can be reduced with the introduction of additional power levels and cycle divisions. For example, in FIG. 16, power levels of 1 and 10\hat{ }-3/2 for corresponding cycles of 1 and 1/4 are used. This can be seen to reduce the distance for signal saturation and loss of signal contrast to 28 m. In FIG. 17, an additional cycle of ¼ at a power of 10\hat{ }-3 is included. This can be seen to further reduce the distance for signal saturation and loss of signal contrast to 4.5 m. The SPADS in these examples have a 4, 3, 2, 1, arrangement as shown below in FIG. 36B.

FIG. 19 illustrates boundary artifacts that can be minimized and corrected by embodiments of the present invention. In this example, histogram 1900 can include a number of counts 1910 in a number of time bins 1920. The counts 1910 in different time bins can vary. For example, counts 1930 can be higher than counts 1932 since counts 1930 can be accumulated over a larger number of cycles, as shown in FIG. 11. Also, artifacts 1940 and 1942 can appear at the boundaries set by the positions of first time bin 1046, second time bin 1048 (both shown in FIG. 10), and other such boundary time bins. These artifacts can be caused by motion, differences in accumulated background, or other factors. These artifacts can be reduced, eliminated, or mitigated by postprocessing in these and other embodiments of the present invention.

Again, embodiments of the present invention can provide lidar systems having improved dynamic range. An example can have emitter elements 132 (shown in FIG. 1) that can provide optical signals over a range of optical power levels. This lidar system can further include sensor elements 142 (shown in FIG. 1) that can detect incident photons. The sensor elements 142 can detect the presence of photons following an emitted optical signal. The emitter elements 132 can emit an optical signal having a series of pulses at a first power level. Following this, circuitry for a pixel, such as pixel 600 (shown in FIG. 6) or other control or other circuitry, can determine a number of incident photons detected during a first number of time bins following each pulse, the first number of time bins beginning with an initial time bin and extending to a final time bin. This can be repeated for tens, hundreds, thousands, or tens of thousands of cycles. The emitter elements 132 can then emit an optical signal having a series of pulses at a second power level. Following this, sensor elements 142 can determine a number of incident photons following each pulse detected during the first number of time bins, the first number of time bins beginning with a time bin that follows the initial time bin and extending to the final time bin. This can be repeated for tens, hundreds, thousands, or tens of thousands of cycles. The number of cycles at the first power level can be different than the number of cycles at the second power level. In this way, when time bins reach their maximum value and saturate following a higher-power optical signal, information can still be recovered from the corresponding time bins following a lower-power optical signal.

In these and other embodiments of the present invention, the second power level can be a higher power level than the first power level. In these and other embodiments of the present invention, the first power level can be a higher power level than the second power level. The optical power levels can be varied in any order and different numbers of power levels can be implemented. For example, optical signals having an intermediate power level can be transmitted first, followed by optical signals having a lower power level, then optical signals having a higher power level.

In these and other embodiments of the present invention, optical signals at two, three, four, five, or more than five power levels can be emitted by emitter elements 132 and sensor elements 142 (shown in FIG. 1) can detect photons following each emitted optical pulse. Optical signals at each power can be emitted for tens, hundreds, thousands, tens of thousands, or more than tens of thousands of cycles. Optical signals at different power levels can be emitted for different numbers of cycles. The resulting bin counts can be combined into a histogram, for example by adding or otherwise combining their values. Where different numbers of cycles are completed at different power levels, processing can be performed before or after the bin values are combined. For example, a first algorithm can be performed on bin values stored following optical signals emitted at a first power level and a second algorithm can be performed on bin values stored following optical signals emitted at a second power level. These algorithms can be used to compensate for difference in background information, motion artifacts, or other factors. The results can then be added or otherwise combined for use in generating a lidar image. An example is shown in the following figure.

FIG. 20A illustrates a method of operating a lidar system according to an embodiment of the present invention. In this example 2000, a first optical signal 2010 including a series of pulses being emitted by emitter elements 132 (shown in FIG. 1) can have a first power level (emitter power level 1.) Following each pulse, sensor elements 142 (shown in FIG. 1) can detect photons during the time corresponding to time bins 2040. This can be repeated for tens, hundreds, thousands, tens of thousands, or more pulses and corresponding cycles. Counts of detected photons can be accumulated in time bins 2040, shown here as a sequence of time bins starting with an initial time bin 2042 and ending with a final time bin N 2048. A second optical signal 2020 having a series of pulses at a second power level (emitter power level 2) can be emitted by emitter elements 132. Following each pulse, sensor elements 142 can detect photons during the time corresponding to time bin K+1 2045 to time bin N 2048. Counts of detected photons can be accumulated in time bins 2040 starting with time bin K+1 2045 and ending with the final time bin N 2048. A third optical signal 1030 having pulses at a third power level (emitter power level 3) can be emitted by emitter elements 132. Following each pulse, sensor elements 142 can detect photons during the time corresponding to time bin M+1 2047 to time bin N 2048. Counts of detected photons can be accumulated in time bins 2040 starting with time bin M+1 2047 and ending with the final time bin N 2048. The accumulated totals following the first optical signal 2010, second optical signal 2020, and third optical signal 2030 can be added together or kept separate for postprocessing.

FIG. 20B illustrates the method of operating a lidar system according to FIG. 20A. In this example 2000, a first optical signal 2010 can be emitted by emitter elements 132 (shown in FIG. 1) and can include a series of pulses having a first power level (emitter power level 1.) Following each pulse, sensor elements 142 (shown in FIG. 1) can detect photons during time 2012. There can be tens, hundreds, thousands, tens of thousands, or more pulses and corresponding cycles. Counts of detected photons can be accumulated as totals 2014 in time bins 2040, shown here as a sequence of time bins starting with an initial time bin 2042 and ending with time bin N 2048. A second optical signal 2020 having a second power level (emitter power level 2) can be emitted by emitter elements 132. Following each pulse, sensor elements 142 can detect photons during time 2022. Counts of detected photons can be accumulated as totals 2024 in time bins 2040 starting with time bin K+1 2046 and ending with time bin N 2048. A third optical signal 2030 having a series of pulses at a third power level (emitter power level 3) can be emitted by emitter elements 132. Following each pulse, sensor elements 142 can detect photons during time 2032. Counts of detected photons can be accumulated as totals 2034 in time bins 2040 starting with time bin M+1 2047 and ending with the final time bin N 2048. The accumulated totals 2014, 2024, and 2034 can be added together or kept separate for postprocessing.

This timing arrangement can be particularly useful where it is expected, based on prior data or other information, that objects are likely to be close and highly reflective. In such a situation, the only contributor to data in time bin 2042 through time bin K 2044, which correspond to short distances from the emitters, are from a low-power optical signals at emitter power level 1.

In this example, some histogram time bins are shown as not being written to during some cycles. This might have minimal impact on a generated lidar image as the contribution to distant objects by lower power optical signals can be negligible. Following a high-power emitter pulse, photons detected at time bins corresponding to shorter distances can have a very low signal-to-power ratio. Omitting this data can help to improve the overall signal-to-noise ratio of the final histogram totals. This reduction can reduce a required amount of memory in pixel 600 (shown in FIG. 6.) It can also decrease the time needed to generate each histogram. In this specific example, the time bins after the first time bin 2042 to time bin K 2044 are not used following emitted optical pulses having the second optical power. Similarly, the time bins after the first time bin 2042 to the time bin M 2046 are not used following emitted optical pulses having the third optical power.

In these and other embodiments of the present invention, the positions of bin K+1 2045 (that is, the bin where binning starts following emitted optical pulses at the second power level), bin M+1 2047 (that is, the bin where binning starts following emitted optical pulses at the third power level), and other such intermediate bins, can be fixed in hardware. Also or alternatively, the positions of these bins can be programmable. Also or alternatively, the positions of these bins can be determined by intraframe, interframe, inter-sub-frame, or intra-sub-frame results. For example, binning can start after or before time bin K+1 2045 following emitted signals at the second power level depending on results accumulated for either a current or previous histogram. Similar variations can be implemented following other attenuated optical signals. Also or alternatively, the positions of these bins can be determined by interactive software.

In these and other embodiments of the present invention, the bins shown as time bin K 2044, time bin M 2046, and other specific bins can be fixed or otherwise positioned at predetermined locations in bins 2040. In these and other embodiments of the present invention, the positions of time bin K 2044, time bin M 2046, and other specific bins can be programmably or otherwise variably positioned in the range of time bins 2040. Limits can be placed on the positions of time bin K 2044 and time bin M 2046 to avoid the necessity of the inclusion of resources or processing that might have a limited utility.

In this example, the third power level can be a higher power level than the second power level, which can be higher than the first power level. This order can be altered in any sequence. For example, the first power level can be a higher power level than the second power level, which can be higher than the third power level, the first power level can be a higher power level than the third power level, which can be higher than the second power level, or any other ranking can be employed.

Optical signals at the first power level can be emitted before optical signals at the second power level, which can be emitted before optical signals at the third power level. These optical signals can be emitted in different orders. For example, optical signals at the third power level can be emitted before optical signals at the second power level, which can be emitted before optical signals at the first power level, optical signals at the first power level can be emitted before optical signals at the third power level, which can be emitted before optical signals at the second power level, or any other sequence can be employed. The optical signals at the different levels can be interspersed or interleaved among each other. For example, some optical signals at the first power level can be emitted followed by some optical signals at the second power level and the third power level, followed by more optical signals at the first power level. This distribution can help to improve heat dissipation in the emitter array.

While three optical power levels are shown in this example, two, four, five, or more than five optical power levels can be used. An example is shown in the following figure.

FIG. 21 is a conceptual histogram generated according to an embodiment of the present invention. In this example 2100, a number of cycles 2120 at a normalized optical power level of 1 are run and results are stored in time bins 2110 corresponding to a maximum distance of 200 meters, though other distances, such as 400 or 800 meters can be used. Optical signals at successively reduced power levels are emitted for cycles 2130, 2140, and 2150 as shown. These cycles can utilize power levels successively reduced to normalized levels 10^{-3/2}, 10⁻³, and 10^{-9/2} as shown. The number of cycles can be one-quarter the nominal number of non-attenuated power level cycles, though in other embodiments of the present invention, other percentages of the nominal number of non-attenuated power level cycles can be used, and the numbers of cycles at each power level can be different. Detected photon data from the sensor elements 142 are binned for successively longer times for emitted optical pulses having lower power. For example, detected photon data following emitted optical data signals at the normalized power level of 10^{-3/2} is binned starting at an earlier time (for an increased number of time bins) than detected photon data following emitted optical data signals at the normalized power level of 1. Similarly, detected photon data following emitted optical data signals at the normalized power level of 10⁻³ is binned starting at an earlier time than detected photon data following emitted optical data signals at the normalized power level of 10^{-3/2}. Similarly, detected photon data following emitted optical data signals at the normalized power level of 10^{-9/2} is binned starting at an earlier time than detected photon data following emitted optical data signals at the normalized power level of 10⁻³.

These and other embodiments can count detected photons for various number of cycles. In one example, a maximum count per time bin can be 16,000. A sensor for each pixel can employ four detector components, such as the detector components or sensor shown in FIG. 30B. In this example, the nominal number of cycles 2120 at an unattenuated power level, or a normalized power level of 1, can be 2,000. Cycles 2130, 2140, and 2150 can include 500 cycles. Each of these power levels can generate up to 2,000 counts each, or 6,000 counts total. The 2000 cycles of cycles 2120 can reach a count of four times that value, or 8000. Other numbers of cycles and other numbers of detector components can be utilized in this and other embodiments of the present invention. The numbers of cycles and numbers of detector components can be fixed, programmable, determined by interactive software, or otherwise set.

### 6. Using Non-Overlapping Sub-Ranges with Power Stepping to Increase Dynamic Range

In the examples of FIG. 10A, FIG. 10B, FIG. 20A, and FIG. 20B, detected results following optical signals at different power levels are stored or accumulated in some of the bins. That is, the binning of results following optical signals can overlap for at least some of the bins. These and other embodiments of the present invention can provide a method of operating a lidar system where there is no such overlap. That is, where each time bin is written to following only one power level. An example is shown in the following figure.

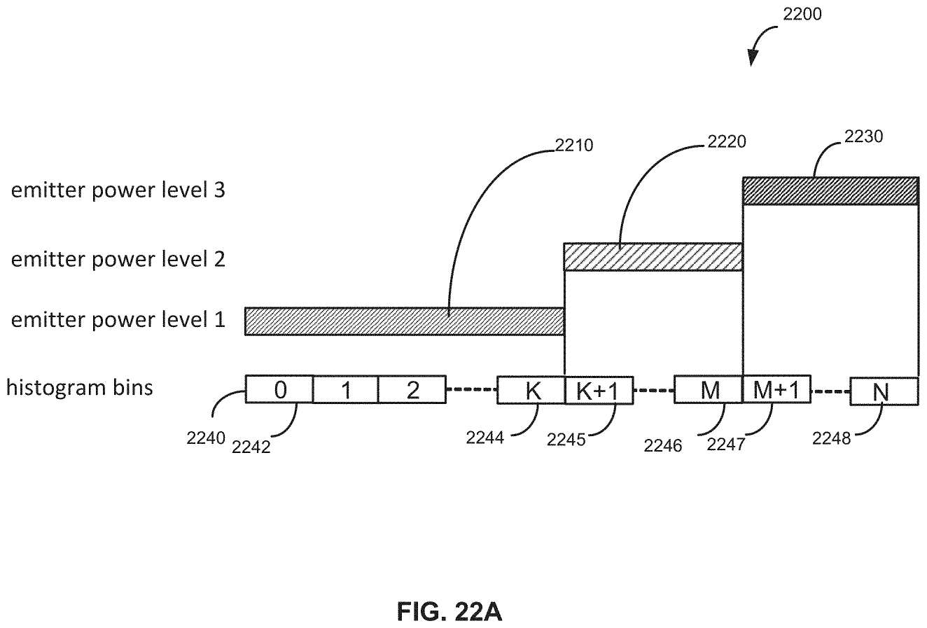

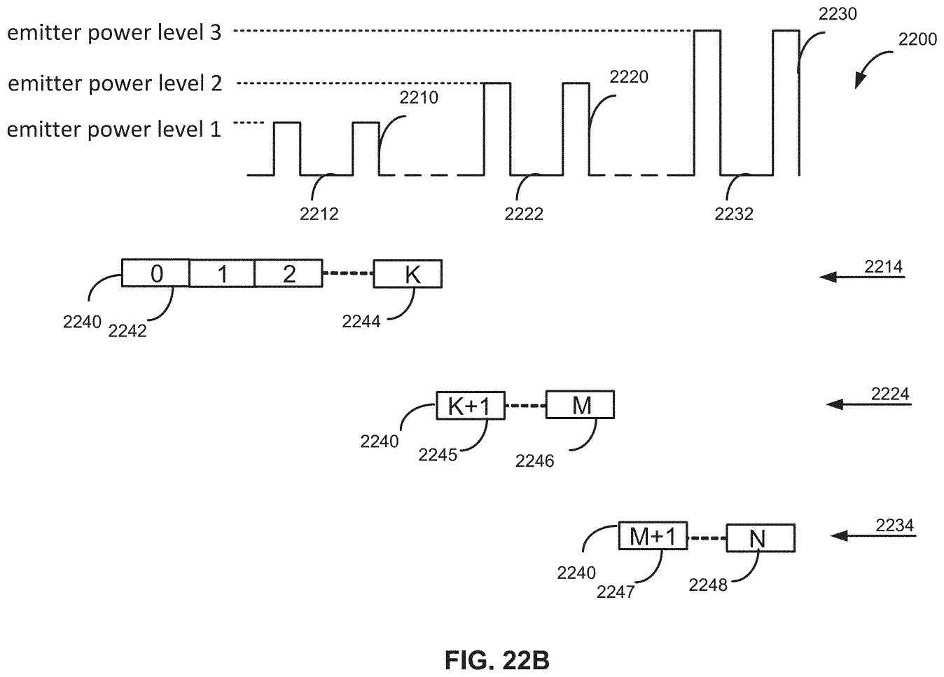

FIG. 22A illustrates a method of operating a lidar system according to an embodiment of the present invention. In this example 2200, a first optical signal 2210 being emitted by emitter elements 132 (shown in FIG. 1) can include a series of pulses having a first power level (emitter power level 1.) Following each pulse, sensor elements 142 (shown in FIG. 1) can detect photons during the time corresponding to time bins 2240 through time bins K 2244. This can be repeated for tens, hundreds, thousands, tens of thousands, or more pulses and corresponding cycles. Counts of detected photons can be stored in time bin 2240 through time bin K 2244. A second optical signal 2220 having pulses at a second power level (emitter power level 2) can be emitted by emitter elements 132. Following each pulse, sensor elements 142 can detect photons during the time corresponding to time bin K+1 2245 to time bin M 2246. Counts of detected photons can be accumulated in time bins 2240 starting with time bin K+1 2245 and ending with the final time bin M 2246. A third optical signal 2230 having a series of pulses at a third power level (emitter power level 3) can be emitted by emitter elements 132. Following each pulse, sensor elements 142 can detect photons during the time corresponding to time bin M+1 2247 to time bin N 2248. Counts of detected photons can be stored in time bins 2240 starting with time bin M+1 2247 and ending with the final time bin N 2248. The accumulated totals following the first optical signal 2210, second optical signal 2220, and third optical signal 2030 can be added together or kept separate for postprocessing.

FIG. 22B illustrates the method of operating a lidar system according to FIG. 22A. In this example 2200, a first optical signal 2210 can be emitted by emitter elements 132 (shown in FIG. 1) and can include a series of pulses having a first power level (emitter power level 1.) Following each pulse, sensor elements 142 (shown in FIG. 1) can detect photons during time 2212. There can be tens, hundreds, thousands, tens of thousands, or more pulses and corresponding cycles. Counts of detected photons can be accumulated as totals 2214 in time bins 2240, shown here as a sequence of time bins starting with an initial time bin 2240 and ending with time bin K 2244. A second optical signal 2220 having a second power level (emitter power level 2) can be emitted by emitter elements 132. Following each pulse, sensor elements 142 can detect photons during time 2222. Counts of detected photons can be accumulated as totals 2224 in time bins 2240 starting with time bin K+1 2245 and ending with time bin M 2246. A third optical signal 2230 having a series of pulses at a third power level (emitter power level 3) can be emitted by emitter elements 132. Following each pulse, sensor elements 142 can detect photons during time 2232. Counts of detected photons can be accumulated as totals 2234 in time bins 2240 starting with time bin M+1 2247 and ending with the final time bin N 2248. The accumulated totals 2214, 2224, and 2234 can be added together or kept separate for postprocessing.

This timing arrangement can be particularly useful since there is no overlap in the binning of results following optical signals at different emitter power levels. This can simplify processing that might otherwise need to be done before an image can be generated.

In this example, some histogram time bins are shown as not being written to during some cycles. This might have minimal impact on a generated lidar image as the contribution to resolving distant objects by lower power optical signals can be negligible. Also, following a high-power emitter pulse, photons detected at time bins corresponding to shorter distances can have a very low signal-to-power ratio. Omitting this data can help to improve the overall signal-to-noise ratio of the final histogram totals. This reduction in binning can simplify circuitry associated with memory in pixel 600 (shown in FIG. 6.) It can also decrease the time needed to generate each histogram. In this specific example, the time bins after time bin K+1 2245 are not used following emitted optical pulses having the first optical power. Similarly, the time bins after time bin M+1 2247 are not used following emitted optical pulses having the third optical power.

In these and other embodiments of the present invention, the positions of time bin K+1 2245 (where binning starts following emitted optical pulses at the second power level), time bin M+1 2247 (where binning starts following emitted optical pulses at the third power level), and other such intermediate time bins, can be fixed in hardware. Also or alternatively, the positions of these time bins can be programmable. Also or alternatively, some of these positions can be programmable while others can be fixed. For example, start times, such as bin K+1 2245 or bin M+1 2247 can be fixed while stop times, such as time bin K 2244 or time bin M 2246 can be programmable. Alternatively, start times, such as bin K+1 2245 or bin M+1 2247 can be programmable while stop times, such as time bin K 2244 or time bin M 2246 can be fixed, or other combinations of fixed and programmable times can be employed. Also or alternatively, the positions of these time bins can be determined by intraframe, interframe, inter-sub-frame, or intra-sub-frame results. For example, binning can start after or before time bin K+1 2245 following emitted signals at the second power level depending on results accumulated for either a current or previous histogram. Similar variations can be implemented following other attenuated optical signals. Also or alternatively, the positions of these time bins can be determined by interactive software.

In these and other embodiments of the present invention, the bins shown as time bin K 2244, time bin M 2246, and other specific bins can be fixed or otherwise positioned at predetermined locations in time bins 2240. In these and other embodiments of the present invention, the positions of time bin K 2244, time bin M 2246, and other specific bins can be programmably or otherwise variably positioned in the range of time bins 2240. Limits can be placed on the positions of time bin K 2244 and time bin M 2246 to avoid the necessity of the inclusion of resources or processing that might have a limited utility.

In this example, the third power level can be a higher power level than the second power level, which can be higher than the first power level. This order can be altered in any sequence. For example, the first power level can be a higher power level than the second power level, which can be higher than the third power level, the first power level can be a higher power level than the third power level, which can be higher than the second power level, or any other ranking can be employed.

Optical signals at the first power level can be emitted before optical signals at the second power level, which can be emitted before optical signals at the third power level. These optical signals can be emitted in different orders. For example, optical signals at the third power level can be emitted before optical signals at the second power level, which can be emitted before optical signals at the first power level, optical signals at the first power level can be emitted before optical signals at the third power level, which can be emitted before optical signals at the second power level, or any other sequence can be employed. The optical signals at the different levels can be interspersed or interleaved among each other. For example, some optical signals at the first power level can be emitted followed by some optical signals at the second power level and the third power level, followed by more optical signals at the first power level. This distribution can help to improve heat dissipation in the emitter array.

While three optical power levels are shown in this example, two, four, five, or more than five optical power levels can be used. An example is shown in the following figure.

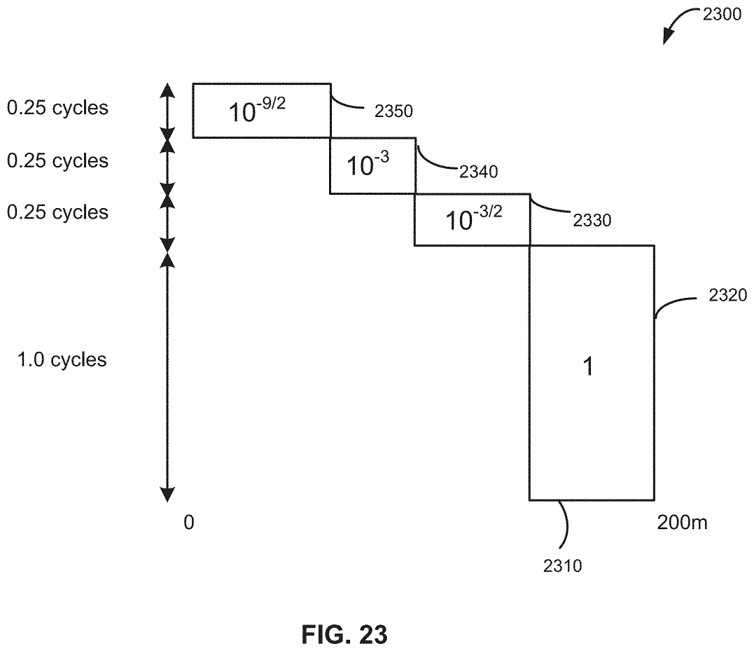

FIG. 23 is a conceptual histogram generated according to an embodiment of the present invention. In this example 2300, a number of cycles 2320 at a normalized optical power level of 1 are run and results are stored in time bins 2310 corresponding to a distance of up to 200 meters, though other distances, such as 400 or 800 meters can be used. Optical signals at successively reduced power levels are emitted for cycles 2330, 2340, and 2350 as shown. These cycles can utilize power levels successively reduced to normalized levels 10^{-3/2}, 10⁻³, and 10^{-9/2} as shown. The number of cycles can be one-quarter the nominal number of non-attenuated power level cycles, though in other embodiments of the present invention, other percentages of the nominal number of non-attenuated power level cycles can be used, and the numbers of cycles at each power level can be different. Detected photon data from the sensor elements 142 (shown in FIG. 1) are binned in earlier bins following emitted optical signals having lower power. For example, detected photon data following emitted optical data signals at the normalized power level of 10^{-3/2} is binned earlier than detected photon data following emitted optical data signals at the normalized power level of 1. Similarly, detected photon data following emitted optical data signals at the normalized power level of 10⁻³ is binned earlier than detected photon data following emitted optical data signals at the normalized power level of 10^{-3/2}. Similarly, detected photon data following emitted optical data signals at the normalized power level of 10^{-9/2} is binned earlier than detected photon data following emitted optical data signals at the normalized power level of 10⁻³.

These and other embodiments can count detected photons for various number of cycles. In one example, a maximum count per time bin can be 16,000. A sensor for each pixel can employ four detector components, such as the detector components or sensor shown in FIG. 30B. In this example, the nominal number of cycles 2320 at an unattenuated power level, or a normalized power level of 1, can be 2,000. Cycles 2330, 2340, and 2350 can include 500 cycles. Each of these power levels can generate up to 2,000 counts each, or 6,000 counts total. The 2000 cycles of cycles 2320 can reach a count of four times that value, or 8000. Other numbers of cycles and other numbers of detector components can be utilized in this and other embodiments of the present invention. The numbers of cycles and numbers of detector components can be fixed, programmable, determined by interactive software, or otherwise set.

### 7. Using Variably-Overlapping Sub-Ranges with Power Stepping to Increase Dynamic Range

In the example of FIG. 22A and FIG. 22B, results might not be stored in a same bin following optical power signals at different power levels. This can simplify post processing that might need to be done to form a final image. But on occasion some overlap might be desirable. For example, overlapping data might be used to normalize or align results following optical signals emitted at different power levels. An example is shown in the following figure.

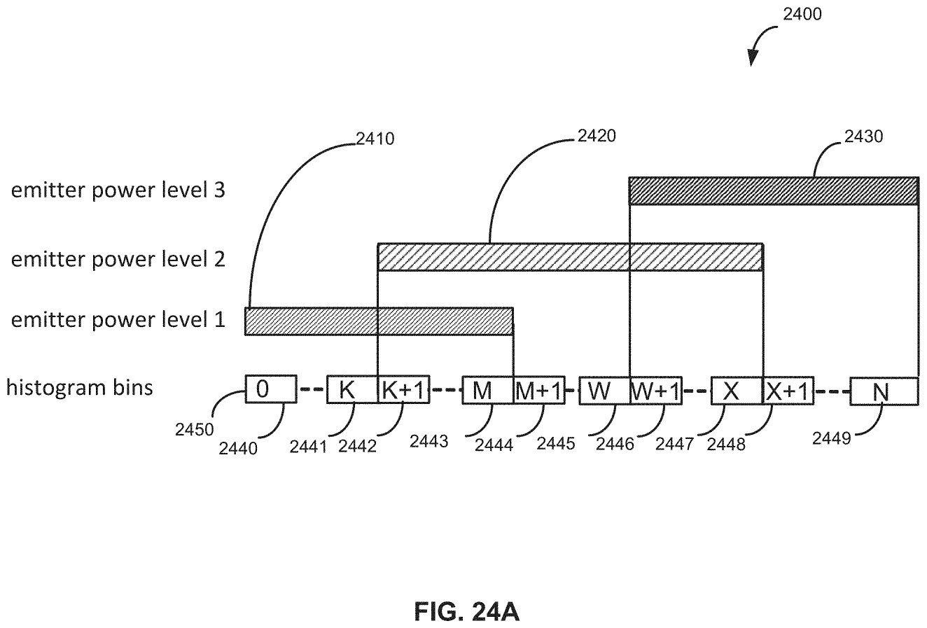

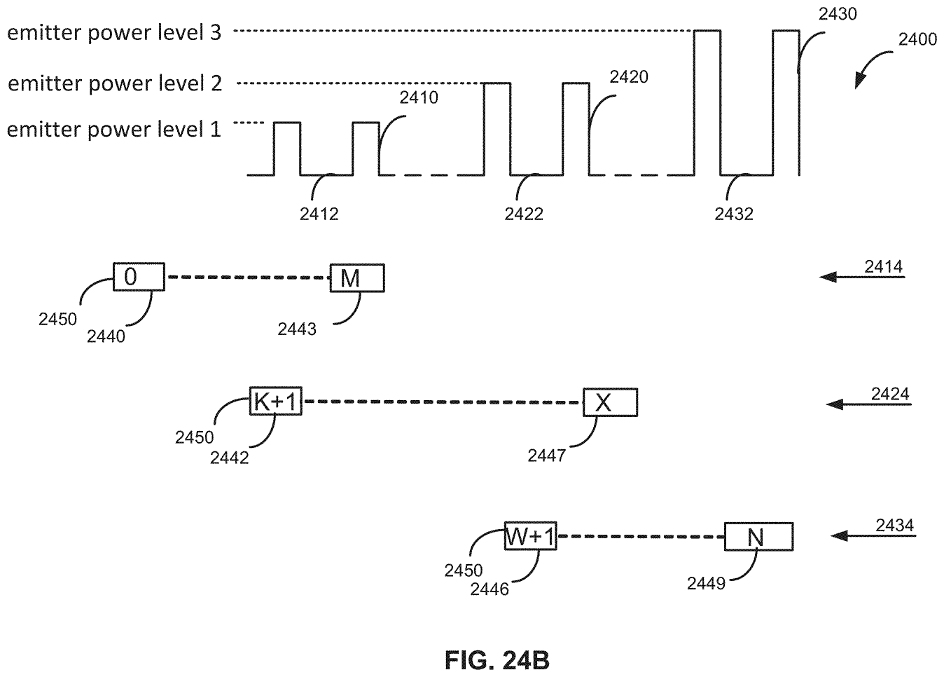

FIG. 24A illustrates a method of operating a lidar system according to an embodiment of the present invention. In this example 2400, a first optical signal 2410 being emitted by emitter elements 132 (shown in FIG. 1) can have a series of pulses at a first power level (emitter power level 1.) Following each pulse, sensor elements 142 (shown in FIG. 1) can detect photons during the time corresponding to time bins 2440 through time bins M 2443. This can be repeated for tens, hundreds, thousands, tens of thousands, or more pulses and corresponding cycles. Counts of detected photons can be accumulated in time bin 2440 through time bin M 2443. A second optical signal 2420 having a series of pulses at a second power level (emitter power level 2) can be emitted by emitter elements 132. Following each pulse, sensor elements 142 can detect photons during the time corresponding to time bin K+1 2442 to time bin X 2447. Counts of detected photons can be stored in time bins 2450 starting with time bin K+1 2442 and ending with time bin X 2447. A third optical signal 2430 having a third power level (emitter power level 3) can be emitted by emitter elements 132. Following each pulse, sensor elements 142 can detect photons during the time corresponding to time bin W+1 2446 to time bin N 2449. Counts of detected photons can be stored in time bins 2450 starting with time bin W+1 2448 and ending with the final time bin N 2449. The accumulated totals following the first optical signal 2410, second optical signal 2420, and third optical signal 2430 can be added together or kept separate for post processing.

FIG. 24B illustrates the method of operating a lidar system according to FIG. 24A. In this example 2400, a first optical signal 2410 can be emitted by emitter elements 132 (shown in FIG. 1) and can include a series of pulses having a first power level (emitter power level 1.) Following each pulse, sensor elements 142 (shown in FIG. 1) can detect photons during time 2412. There can be tens, hundreds, thousands, tens of thousands, or more pulses and corresponding cycles. Counts of detected photons can be accumulated as totals 2414 in time bins 2450, shown here as a sequence of time bins starting with an initial time bin 2440 and ending with time bin M 2443. A second optical signal 2420 having a second power level (emitter power level 2) can be emitted by emitter elements 132. Following each pulse, sensor elements 142 can detect photons during time 2422. Counts of detected photons can be accumulated as totals 2424 in time bins 2450 starting with time bin K+1 2442 and ending with time bin X 2447. A third optical signal 2430 having a series of pulses at a third power level (emitter power level 3) can be emitted by emitter elements 132. Following each pulse, sensor elements 142 can detect photons during time 2432. Counts of detected photons can be accumulated as totals 2434 in time bins 2450 starting with time bin W+1 2446 and ending with the final time bin N 2449. The accumulated totals 2414, 2424, and 2434 can be added together or kept separate for post processing.

This timing arrangement can be useful where the binning of results following optical signals at different emitter power levels is desired. This can be used to normalize or align data following optical signals at different emitter power levels.

In this example, some histogram time bins are shown as not being written to during some cycles. This might have minimal impact on a generated lidar image as the contribution to resolving distant objects by lower power optical signals can be negligible. Also, following a high-power emitter pulse, photons detected at time bins corresponding to shorter distances can have a very low signal-to-power ratio. Omitting this data can help to improve the overall signal-to-noise ratio of the final histogram totals. This reduction in binning can simplify circuitry associated with memory in pixel 600 (shown in FIG. 6.) It can also decrease the time needed to generate each histogram. In this specific example, the time bins after time bin M+1 2444 are not used following emitted optical pulses having the first optical power. Similarly, the time bins after time bin X+1 2448 are not used following emitted optical pulses having the third optical power. This allows results measurements to cease and a new cycle to begin earlier.

In these and other embodiments of the present invention, the positions of bin K+1 2442 (that is, the bin where binning starts following emitted optical pulses at the second power level), bin W+1 2446 (that is, the bin where binning starts following emitted optical pulses at the third power level), and other such intermediate bins, can be fixed in hardware. Also or alternatively, the positions of these bins can be programmable. Also or alternatively, some of these positions can be programmable while others can be fixed. For example, start times, such as bin K+1 2442 or bin W+1 2446, can be fixed while stop times, such as time bin M 2443 or time bin X 2447 can be programmable. Alternatively, start times, such as time bin K+1 2442 or time bin W+1 2446 can be programmable while stop times, such as time bin M 2443 or time bin X 2447 can be fixed, or other combinations of fixed and programmable times can be employed. Also or alternatively, the positions of these bins can be determined by intraframe, interframe, inter-sub-frame, or intra-sub-frame results. For example, binning can start after or before time bin K+1 2442 following emitted signals at the second power level depending on results accumulated for either a current or previous histogram. Similar variations can be implemented following other attenuated optical signals. Also or alternatively, the positions of these bins can be determined by interactive software.

In these and other embodiments of the present invention, the bins shown as time bin K 2441, time bin M 2443, and other specific bins can be fixed or otherwise positioned at predetermined locations in time bins 2440. In these and other embodiments of the present invention, the positions of time bin K 2441, time bin M 2443, and other specific bins can be programmably or otherwise variably positioned in the range of time bins 2450. Limits can be placed on the positions of time bin K 2441 and time bin M 2443 to avoid the necessity of the inclusion of resources or processing that might have a limited utility.

In this example, the third power level can be a higher power level than the second power level, which can be higher than the first power level. This order can be altered in any sequence. For example, the first power level can be a higher power level than the second power level, which can be higher than the third power level, the first power level can be a higher power level than the third power level, which can be higher than the second power level, or any other ranking can be employed.

Optical signals at the first power level can be emitted before optical signals at the second power level, which can be emitted before optical signals at the third power level. These optical signals can be emitted in different orders. For example, optical signals at the third power level can be emitted before optical signals at the second power level, which can be emitted before optical signals at the first power level, optical signals at the first power level can be emitted before optical signals at the third power level, which can be emitted before optical signals at the second power level, or any other sequence can be employed. The optical signals at the different levels can be interspersed or interleaved among each other. For example, some optical signals at the first power level can be emitted followed by some optical signals at the second power level and the third power level, followed by more optical signals at the first power level. This distribution can help to improve heat dissipation in the emitter array.

While three optical power levels are shown in this example, two, four, five, or more than five optical power levels can be used. An example is shown in the following figure.

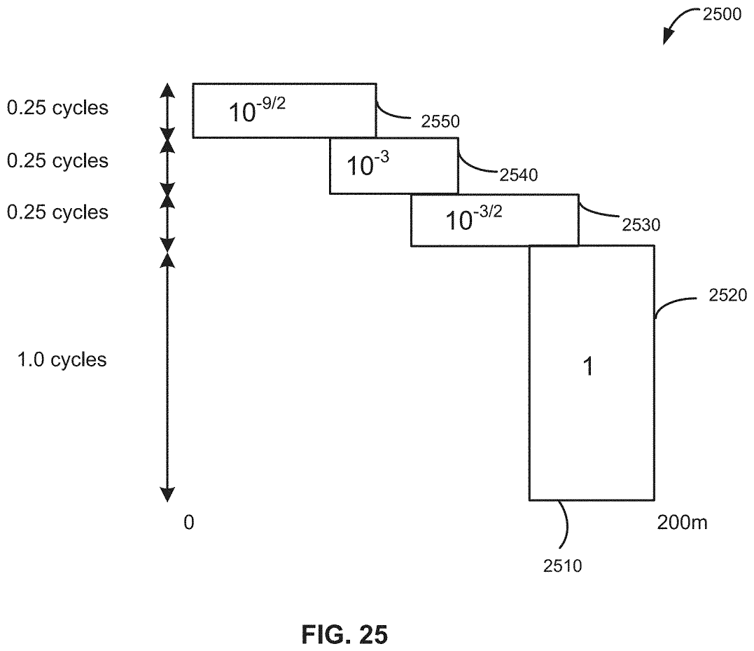

FIG. 25 is a conceptual histogram generated according to an embodiment of the present invention. In this example 2500, a number of cycles 2520 at a normalized optical power level of 1 are run and results are stored in time bins 2510 corresponding to a distance of up to 200 meters, though other distances, such as 400 or 800 meters can be used. Optical signals at successively reduced power levels are emitted for cycles 2530, 2540, and 2550 as shown. These cycles can utilize power levels successively reduced to normalized levels 10^{-3/2}, 10⁻³, and 10^{-9/2} as shown. The number of cycles can be one-quarter the nominal number of non-attenuated power level cycles, though in other embodiments of the present invention, other percentages of the nominal number of non-attenuated power level cycles can be used, and the numbers of cycles at each power level can be different. Detected photon data from the sensor elements 142 are binned in earlier bins following emitted optical pulses having lower power. An amount of overlap can be present among results following optical signals having different power levels. For example, detected photon data following emitted optical data signals at the normalized power level of 10^{-3/2} is binned in earlier and overlapping bins with detected photon data following emitted optical data signals at the normalized power level of 1. Similarly, detected photon data following emitted optical data signals at the normalized power level of 10⁻³ is binned in earlier and overlapping bins with detected photon data following emitted optical data signals at the normalized power level of 10^{-3/2}. Similarly, detected photon data following emitted optical data signals at the normalized power level of 10^{-9/2} is binned in earlier and overlapping bins with emitted optical data signals at the normalized power level of 10⁻³.

These and other embodiments can count detected photons for various number of cycles. In one example, a maximum count per time bin can be 16,000. A sensor for each pixel can employ four detector components, such as the detector components or sensor shown in FIG. 30B. In this example, the nominal number of cycles 2520 at an unattenuated power level, or a normalized power level of 1, can be 2,000. Cycles 2530, 2540, and 2550 can include 500 cycles. Each of these power levels can generate up to 2,000 counts each, or 6,000 counts total. The 2000 cycles of cycles 2520 can reach a count of four times that value, or 8000. Other numbers of cycles and other numbers of detector components can be utilized in this and other embodiments of the present invention. The numbers of cycles and numbers of detector components can be fixed, programmable, determined by interactive software, or otherwise set.

In these and other embodiments of the present invention, the optical power can be varied among two, three, four, or more than four levels. That is, the emitters can provide an optical signal at a number of distinct emitter power levels, shown above as emitter power level 1, emitter power level 2, and emitter power level 3. Pulses at one of these emitter power levels are emitted and counts of detected photons are accumulated in a number of time bins following each pulse.

### 8. Using Variable Integration Time with Power Ramping to Increase Dynamic Range

In these and other embodiments of the present invention, the emitted power can be ramped over a number of cycles. That is, the emitted power can be ramped up over a number of cycles, or the emitted power can be ramped down over a number of cycles. The emitted power can start at a low level for a first cycle. The emitted power can increase or decrease each following cycle. Alternatively, the emitted power can remain at a level for a number of cycles and can then be increased to or decreased to a new level for one or more cycles.

To help maintain a constant dynamic range, the integration time following each emitted pulse can be varied. There can be at least two ways to vary the integration time. First, the integration time can be decreased by reducing the number of time bins used following an emitted optical signal. For example, time bins corresponding to a short distance are be used while time bins corresponding to a longer distance are not used following a low power pulse, as shown in the example of FIG. 10 above.

Second, the duration of each time bin can be varied. That is, the integration time can be decreased by reducing a length of each time bin. This can be useful by increasing the resolution at shorter distances. Accordingly, embodiments of the present invention can emit low-power pulses and then shorten time bins over which data is gathered. The integration time can be increased by lengthening each time bin. This can increase a distance for which measurements can be made. Accordingly, embodiments of the present invention can emit higher power pulses and then lengthen time bins over which data is gathered. When the length of each time bin is varied, data can be gathered for all of the possible time bins, for example time bin 2440 through time bin N 2449 (shown in FIG. 24.) Alternatively, when the length of each time bin is varied, data can be gathered for some of the possible time bins, for example time bin 2440 through time bin M 2444 (shown in FIG. 24.) Examples are shown in the following figures.

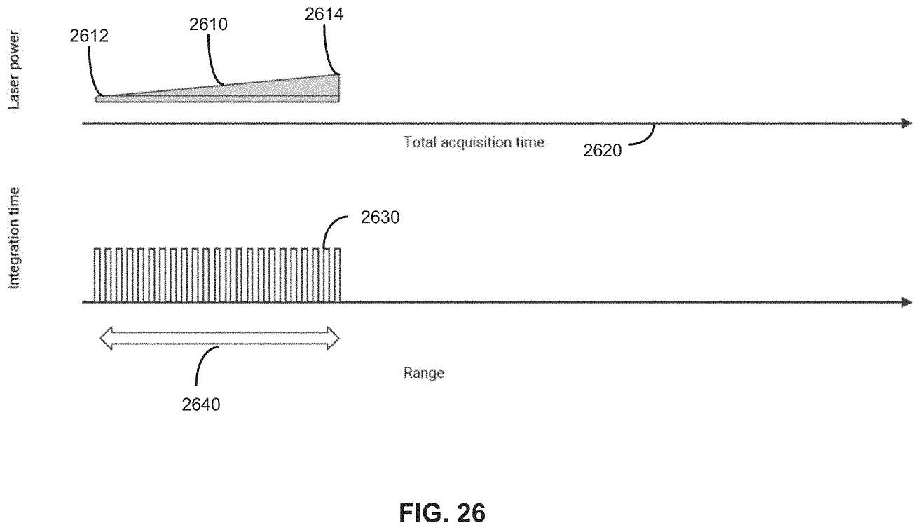

FIG. 26 illustrates a method of operating a lidar system according to an embodiment of the present invention. In this example, emitted laser power 2610 can be ramped from a first value 2612 to a second value 2614 over time 2620. Laser power 2610 can be increased following each emitted pulse, the laser power can be increased in distinct steps, or the laser power can be increased in other ways. The integration time 2630 can remain fixed or it can be increased as well. In this example, the integration time can remain low while emitted laser power 2610 is increased. Alternatively, the integration time 2630 can be increased following each increase in emitted laser power 2610, integration time 2630 can be increased in distinct steps, or integration time 2630 can be increased in other patterns. The integration time 2630 can be made short by either shortening the duration of each time bin, by reducing the number of time bins for which data is accumulated following an emitted optical pulse, or both. In one example, to provide good, short distance resolution, low power emitted pulses can be followed by results being binned in each available time bin, and where the duration of measurement for each time bin is reduced. In this way, the use of shorter time bins provides a greater distance resolution in the final image. Using all available bins provides this increased resolution for the longest distance possible.

In the example of FIG. 26, the integration time 2630 can remain constant when measurements at a short range 2640 are made. As the range is lengthened, the integration time 2630 can be increased. The integration time 2630 can be increased by lengthening the duration of each time bin, or by using more time bins. To make good use of the available time bins, measurements can be delayed for a time following each optical signal pulse. An example is shown in the following figure.

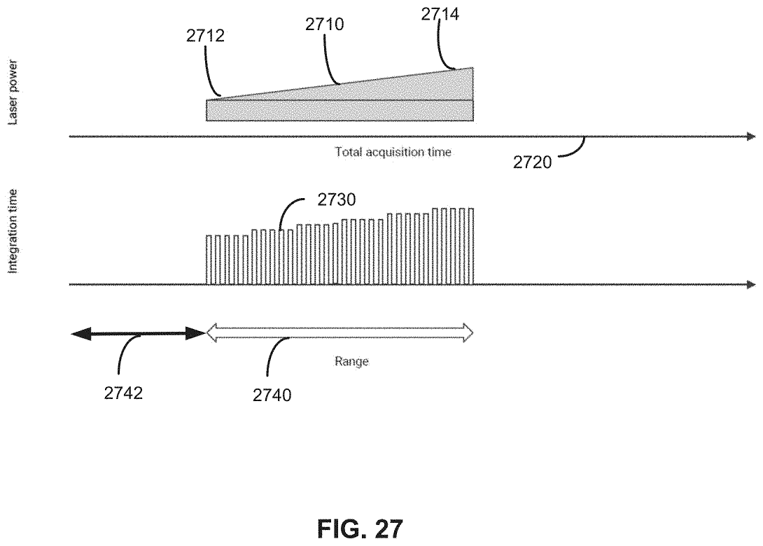

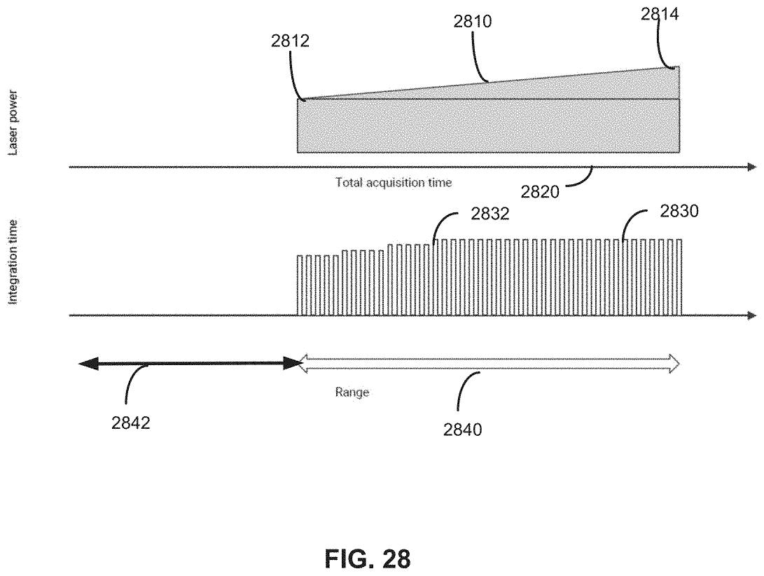

FIG. 27 illustrates a method of operating a lidar system according to an embodiment of the present invention. In this example, emitted laser power 2710 can be ramped from a first value 2712 to a second value 2714 over time 2720. Laser power 2710 can be increased following each emitted pulse, laser power 2710 can be increased in distinct steps following a number of pulses, or laser power 2710 can be increased in other ways. The integration time 2730 can remain fixed or it can be increased as well. In this example, the integration time can be increased while emitted laser power 2710 is increased. This increase can be such that integration time 2730 is increased following each increase in emitted laser power 2710, integration time 2730 can be increased in distinct steps, or integration time 2730 can be increased in other patterns. The integration time 2730 can be made longer by either increasing the duration of each time bin, by increasing the number of time bins for which data is accumulated following an emitted optical pulse, or both. In one example, to provide good, medium distance resolution, medium power emitted pulses can be followed by results being binned in each available time bin, and where the beginning of the measurements is delayed by a time corresponding to range 2742. The delay corresponding to range 2742 can allow the use of shorter time bins that would be otherwise possible, thereby providing greater resolution in the final image data. Using all available bins provides this increased resolution for the longest distance possible.

In the example of FIG. 27, the integration time can be increased as measurements at a progressively longer range are made. As the range is lengthened, the integration time can be increased. The integration time can be increased by lengthening the duration of each time bin, or by using more time bins. To make good use of the available bins, measurements can be delayed for a time following each optical signal pulse. An example is shown in the following figure.

FIG. 28 illustrates a method of operating a lidar system according to an embodiment of the present invention. In this example, emitted laser power 2810 can be ramped from a first value 2812 to a second value 2814 over time 2820. Laser power 2810 can be increased following each emitted pulse, laser power 2810 can be increased in distinct steps following a number of pulses, or laser power 2810 can be increased in other ways. The integration time 2830 can remain fixed or it can be increased as well. In this example, the integration time 2830 can be increased while emitted laser power 2810 is increased until integration time 2832 is reached. This increase can be such that integration time 2830 is increased following each increase in emitted laser power 2810, integration time 2830 can be increased in distinct steps, or integration time 2830 can be increased in other patterns. The integration time can be made longer by either increasing the duration of each time bin, by increasing the number of time bins for which data is accumulated following an emitted optical pulse, or both. In one example, to provide good, long distance resolution, high-power emitted pulses can be followed by results being binned in each available time bin, and where the beginning of the measurements is delayed by a time corresponding to range 2842. The delay corresponding to range 2842 can allow the use of shorter time bins that would be otherwise possible, thereby providing greater resolution in the final image data. Using all available bins provides this increased resolution for the longest distance possible.

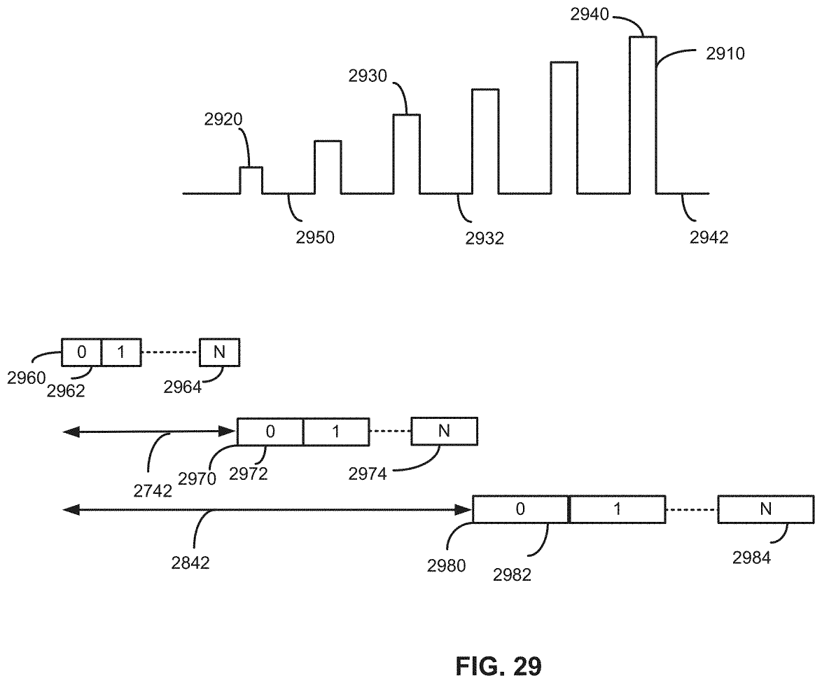

FIG. 29 further illustrates the method of FIG. 26 through FIG. 28. In this example a series of pulses 2910 can be emitted by emitters. The pulses can include short-range low-power pulses 2920, medium-range medium-power pulses 2930, and long-range high-power pulses 2940. Following each pulse, sensor elements 142 (shown in FIG. 1) can detect photons during a corresponding time 2950. The number of detected photons can be accumulated for short-range pulses 2920 in time bins 2960, starting with time bin 2962 and extending to time bin 2964. In this example, time bins 2960 can be short and the time corresponding to time bins 2960 can be similarly short and corresponding to a short-range. This can have the advantage or providing an increased resolution at short distances.

The number of detected photons can be accumulated during times 2932 for medium-range pulses 2930 in time bins 2970, starting with time bin 2972 and extending to time bin 2974. In this example, time bins 2970 can be medium in duration and the time corresponding to time bins 2970 can be similarly medium and corresponding to a medium-range. This can have the advantage or providing a good resolution at medium distances. Since medium distances are being measured, data is not collected for a time corresponding to range 2742.

The number of detected photons can be accumulated during times 2942 for long-range pulses 2940 in time bins 2980, starting with time bin 2982 and extending to time bin 2984. In this example, time bins 2980 can be longer in duration and the time corresponding to time bins 2980 can be similarly longer and corresponding to a longer range. This can have the advantage or providing a resolution at a long distance. Since long distances are being measured, data is not collected for a time corresponding to range 2842, which can be longer than range 2742.

### 9. Memory Usage and Control in Systems Having Increased Dynamic Range

The photon counts indicated by the detection signals collected by the lidar system may include signal photons, which are correlated to the emitter pulses (e.g., based on respective times of arrival/detection within a correlation window), and background photons bg, which are not correlated to the emitter pulses (e.g., based on respective times of arrival/detection outside of the correlation window). Counts of background photons may mostly be Poisson distributed, for example, resulting from solar photons or from dark counts of the SPAD which may be pixel- and/or temperature-dependent. The counts of the background photons may thus be indicative of background light conditions (also referred to as background light levels) in the operating environment.

Some embodiments of the present disclosure may arise from realization that, while background photon counts may not be a function of the distance of a target from the lidar system, signal photon counts may be inversely proportional to the square of the distance of the target. Because the signal to noise ratio (SNR) is proportional to the signal counts at the square root of the background counts (i.e., SNR scales with s/sqrt(bg)), it may be desirable to image longer distance subranges (e.g., for detection of distant targets) over more emitter cycles than shorter distance subranges (e.g., for detection of nearby targets).

In particular, SNR can be derived from the following equations:

$${E}_{d} = \frac{ρ κ η ω {A}_{l} E}{π Ω {R}^{2}} ; \\ s = {E}_{d} / ϵ ; \\ bg = \frac{α ω {A}_{l} τ B}{π ϵ} = ; n = sqrt ( bg ) ; \\ SNR 1 = s / sqrt ( bg ) ; \\ SNRC = sqrt ( C ) \times s / sqrt ( bg ) ,$$

where the subscript C indicates the number of measurements or laser cycles, s is the signal counts, and bg is the background counts.

As such, SNR decreases with the square of the range, R. In order to maintain SNR over the desired imaging distance range, C can be scaled up for detection of more distant targets. That is, more measurements or laser cycles may be used for imaging farther distance subranges in order to increase or maintain the desired signal to noise ratio. However, as the number of background counts bg is not a function of the range R, integration over a longer number of emitter cycles may result in the counting of more background photons, which requires more memory.

Accordingly, some embodiments of the present disclosure may provide lidar detector circuits including a plurality of detector pixels, with each detector pixel having one or more detector elements, and a memory device including respective memory storage locations or memory banks that are configured to store photon count data for respective time bins of a histogram. A control circuit is configured to collect the photon count data over fewer emitter cycles with smaller memory utilization (e.g., fewer of the memory banks) when imaging closer distance subranges, and to collect the photon count data over more emitter cycles with larger memory utilization (e.g., more of the memory banks) when imaging farther distance subranges. Thus, closer targets may require fewer laser cycles and a smaller memory bank while distant targets require more laser cycles and a larger memory bank.

As noted above with reference to FIG. 1, a lidar system 100 includes a pulsed emitter array 130 including a number of emitter elements 132 and a sensor array 140 including a number of sensor elements 142. The period or the pulse repetition cycle of the optical signals output from the emitter elements 132 may be longer than the round trip time to the farthest detectable target of the system 100. Each detector pixel in the sensor array 140 can include one or more sensor elements 142, e.g., SPADs.

As shown in FIG. 30, an array-element memory array (“memory array”) is configured to store photon information for one or more detector pixels. The photon information may be stored in the memory a histogram format, with data indicating counts of detected photons stored in respective memory bins corresponding to histogram time bins, which indicate respective times-of-arrival of the detected photons. In the example of FIG. 30, a memory 3000 includes a photodetector interface circuit 3010 configured to receive detection signals from one or more photodetectors (e.g., SPADs), a sampler circuit 3002 configured to sample the detection signals output from the photodetectors 110d, a main memory device 3005a including a plurality of memory banks 3005b configured to store histogram data, and a memory controller circuit 3005c (e.g., M-bit PRMW logic, corresponding to the number of bit lines M in the memory device 3005a) that is configured to manage operations of the interface circuit 3010, the sampler 3002, and the main memory device 3005a to store and integrate data indicated by the detection signals output from the photodetectors into the histogram data.

In some embodiments, the total memory bits in a memory device 3005a is a product of the number of bins (N) in a histogram, and the number of counts or bits (M) per bin before saturation (illustrated as a N×M memory device). The number of memory bins N may be a function of the longest time-of-flight to be recorded (corresponding to the distance range of a most distant target to be imaged) and the temporal resolution of a histogram (corresponding to its range resolution). For example, if the longest imaging distance range of a lidar system is 300 m and the temporal resolution of each bin is 10 cm, then N=3,000 bins may be required per memory array. If the number of counts (or bits) per bin M=40, then the N×M memory array size may be 120,000 bits.

The control circuit 3005c may be configured to vary or change the number of memory banks and/or the allocation of respective memory banks to the respective time bins or arrival times based on the distance subrange being imaged, which in some embodiments may correspond to respective subframes of an image frame. As noted above, each subframe may include data collected over multiple emitter cycles. In some embodiments, the storage locations (i.e., memory bank addressing) may be swapped and/or iterated (e.g., through the use of multiplexer and/or other type of memory pointer) to change the location at which the avalanche counts are stored based on the distance range/subrange being imaged, such that the time bin allocation of each memory bank may change over the total number of emitter cycles used to collect data for an image frame.

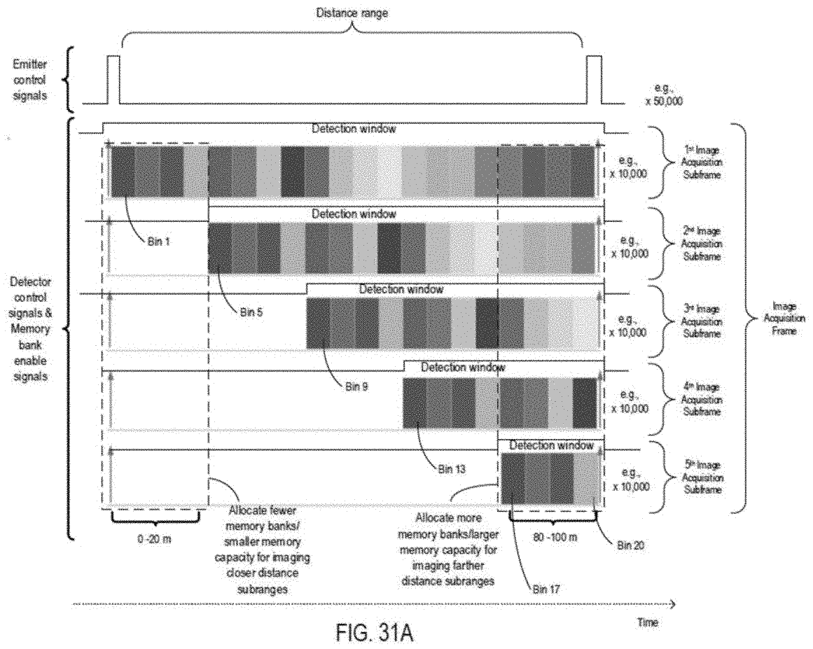

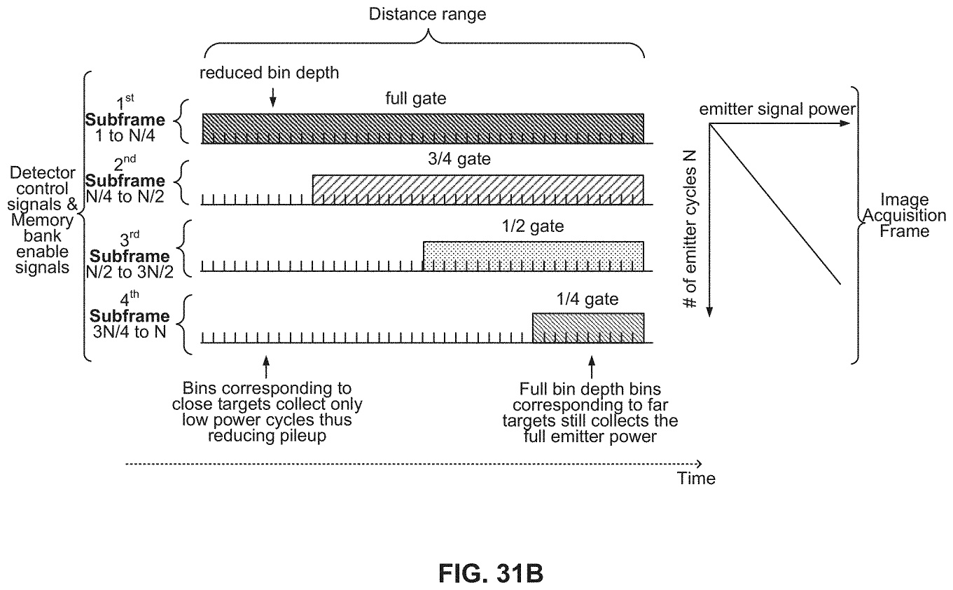

Operations performed by one or more control circuits in accordance with some embodiments of the present disclosure, such as the control circuit 3005c of FIG. 30, are illustrated in FIG. 31A. In the example of FIG. 31A, there are 20 memory banks, each depicted as a different color or shading. Each memory bank may be allocated to store photon data corresponding to a specific histogram time bin or photon arrival time range for a subset of the emitter pulse cycles. The subset of the emitter pulse cycles (illustrated as 10,000 cycles by way of example) may define a subframe of data collection for an imaging frame.

In addition, the bin allocation of each memory bank is changed for subsequent subsets of the emitter pulse cycles (e.g. every 10,000 cycles), such that the bin allocation of each memory bank is varied over the course of an imaging frame (illustrated as including 50,000 cycles per frame by way of example). For example, the control circuit may include a timing circuit that is configured to reallocate the memory banks after a respective subset of the emitter pulse cycles, such that the memory banks store data corresponding to different histogram bin/photon arrival time range than the allocation of the memory banks for the previous subset of the emitter pulse cycles. That is, the image frame may represent data collected over a plurality of emitter pulse cycles, the timing circuit may allocate a first subset of the memory banks to store data corresponding to a particular set of histogram bins for a first subset of the emitter pulse cycles and may allocate the first subset of the memory banks to store data corresponding to a different set of histogram bins for a subsequent subset of the emitter pulse cycles.

As noted above, in the example shown in FIG. 31A, there are 50,000 laser cycles per image frame (e.g., 10,000 laser cycles per subframe, with 5 subframes illustrated). During a first subset of the emitter pulse cycles (e.g., the first subframe in FIG. 31A), many or all of the memory banks may be allocated to respective time bins/photon arrival time ranges, e.g., with the purple bank corresponding to time bin 1 and the brown bank corresponding to bin 5. During a subsequent subset of the emitter pulse cycles (e.g., the second subframe in FIG. 31A), a timing circuit directs avalanche counts to a different subset of the memory banks, e.g., with the purple bank corresponding to time bin 5 and the brown memory bank corresponding to time bin 9. Continuing in this manner for the subsequent subsets of the emitter pulse cycles (e.g., the third, fourth, and fifth subframes in FIG. 31A), the memory banks may be allocated to different time bins for different subframes of the image frame.

For example, with reference to FIG. 31A, if there are no targets present in the field of view, each of the memory banks 1-20 may record data indicating only background photon counts. The first subset of four memory banks 1-4 will accumulate photon count data over 50,000 laser cycles (i.e., for subframes 1 to 5), the second subset of four memory banks 5-8 will accumulate photon count data over 40,000 cycles (i.e., for subframes 1-4), the third subset of four memory banks 9-12 will accumulate photon count data over 30,000 cycles (i.e., for subframes 1-3), the fourth subset of four memory banks 13-16 will accumulate photon count data over 20,000 cycles (i.e., for subframes 1-2), and the fifth subset of four memory banks 17-20 will accumulate photon count data over 10,000 cycles (i.e., for subframe 1 only). At the end of the frame, a processing circuit (such as the processor circuit 210 of FIG. 2) may determine a ratio of counts to be approximately 5:4:3:2:1 in these groups or subsets of four memory banks each, indicating no target was detected.

In another example with reference to FIG. 31A, the target may be present at a distance range corresponding to time bin 1. In this example, only the purple memory bank will record the signal counts, and it will only do so for emitter pulse cycles 1-10,000 (i.e., for subframe 1). At the end of a frame, the number of counts in the purple memory bank will be higher than on the other banks among its group or subset of four memory banks 1-4, and therefore the processing circuit may determine that the distance of the target corresponds to time bin 1. That is, if the peak photon count data appears only in one bin or memory bank, it can be determined to have been collected during subframe 1 only, and thus belongs to a time bin corresponding to the first distance subrange; if it appears in two bins or memory banks, it can be determined to have been collected during subframes 1 and 2, and thus belongs to a time bin corresponding to the second distance subrange; if it appears in three bins or memory banks, it can be determined to have been collected during subframes 1, 2, and 3, and thus belongs to a time bin corresponding to the third distance subrange, etc. More generally, the control circuit may identify the memory bank with the first signal return and may then search or check for existing returns in memory banks with a predetermined period (in this example, a period of 4).

In another example with reference to FIG. 31A, the target may be present at a distance range corresponding to time bin 5. The photon count data will be recorded in the brown bank for the first 10,000 cycles (i.e., for subframe 1) and in the purple bank for the second 10,000 cycles (i.e., for subframe 2). At the end of a frame, the processing circuit may determine that two banks include peak photon count data, and (based on the photon counts among the other banks in the same subset/group) may identify the correct bin as #5 (based on photon count data collection during only subframes 1 and 2, and thus corresponding to the second distance subrange). In this case, 20,000 acquisitions may be used for determining the bin position, twice as many as in the previous example, where the target distance was shorter (corresponding to time bin 1).

In another example with reference to FIG. 31A, the target may be present at a distance range corresponding to time bin 20. The photon count data will be recorded in the red bank for subframe 1, in the pink bank for subframe 2, in the yellow bank for subframe 3, in the dark green bank for subframe 4, and in the light blue bank for subframe 5. At the end of a frame, the processing circuit may determine that five banks include peak photon count data, and (based on the photon counts among the other banks in the same subset/group) may identify the correct bin as #20. In this case, 50,000 acquisitions may be used for determining the bin position.

Further operations performed by one or more control circuits in accordance with some embodiments of the present disclosure, such as the control circuit 3005c of FIG. 30, are illustrated in FIG. 31B. In the example of FIG. 31B, the number of memory banks may be varied (without varying the time bin allocation) based on the distance subrange being imaged. FIG. 31B illustrates 40 memory banks, each allocated to store photon data corresponding to a specific histogram time bin or photon arrival time range. The number of memory banks being utilized or enabled is reduced for subsequent subsets of the emitter pulse cycles (e.g. every N emitter cycles).

For example, as shown in FIG. 31B, most or all of the memory banks may be enabled for a first subset of the N emitter cycles (shown as 1 to N/4) corresponding to a first imaging subframe. For a second subset of the N emitter cycles (shown as N/4 to N/2) corresponding to a second imaging subframe, the memory banks including bins allocated or corresponding to closer distance subranges may not be enabled, such that fewer memory banks may be enabled for the second subframe in comparison to the first subframe. Likewise, for a third subset of the N emitter cycles (shown as N/2 to 3N/4) corresponding to a third imaging subframe, the memory banks including bins allocated or corresponding to the closer half of the distance subranges may not be enabled, such that still fewer memory banks may be enabled for the third subframe in comparison to the second subframe. Similarly, for a fourth subset of the N emitter cycles (shown as 3N/4 to N) corresponding to a fourth imaging subframe, only the memory banks including bins allocated or corresponding to farther distance subranges may be enabled.

As such, the memory banks including bins allocated or corresponding to farthest distance subranges may be enabled to collect data over more emitter cycles of the imaging frame (shown as over all of N the emitter cycles/four subframes), while memory banks including bins allocated or corresponding to closest distance subranges may be enabled to collect data over fewer emitter cycles of the imaging frame (shown as over N/4 emitter cycles/one subframe).

That is, in FIG. 31B, the memory banks including bins allocated or corresponding to the closer distance subranges are exposed or utilized in data collection for only a fraction (as shown, one-fourth) of the N emitter cycles. For subsequent subsets of the N emitter cycles, the gate start (e.g., the timing of the memory bank enable signals) is progressively postponed, thus allowing for wasting less IC power in collecting background photons.

In the example of FIG. 31B, the emitter signal power is also increased over the data collection for the imaging frame, such that lower emitter signal power is output for emitter cycles used in imaging closer distance subranges (which may thereby reduce pileup) and a higher emitter signal power is output for emitter cycles used in imaging farther distance subranges. That is, a power ramp can be applied to the emitters, such that higher emitter signal power is used for imaging farther distance subranges. While illustrated as linearly increasing emitter signal power with the number of emitter cycles N in FIG. 31B, it will be understood that other suitable or optimized power ramp shapes can be applied.

Additionally or alternatively, the application of a power ramp to the emitters can be used in conjunction with a strobing scheme to control the timing and/or duration of activation of one or more detectors such that photon detection and histogramming is performed sequentially over respective time windows, each corresponding to a respective distance subrange. For example, distance subranges from 0 to one-fourth of the total distance range may be imaged during the first N/4 emitter cycles, distance subranges from one-fourth to one-half of the total distance range may be imaged during the second N/4 emitter cycles, distance subranges from one-half to three-fourths of the total distance range may be imaged during the third N/4 emitter cycles, and distance subranges from three-fourths to the total distance range may be imaged during the fourth N/4 emitter cycles. This scheme can be similar to some detector strobing and emitter power stepping schemes, but without reading out each strobe separately. Combinations of any of the control schemes described with reference to FIGS. 31A and 31B may also be used.

A readout operation may be performed by the memory controller 3005c and the detection event count may be reset before sampling the next set of detection signals. That is, a readout operation may be performed at the end of each subframe, with multiple subframes (in some embodiments, each corresponding to a respective detection window or distance subrange) making up each image frame. An image frame may be defined when readout operations have been performed for all detection windows (e.g., the single strobe window covering the entire imaging distance range of the sensor, or multiple strobe windows covering respective distance subranges of the imaging distance range, that is, when data for all subframes (and thus, all distance subranges) have been collected.

Another issue which may occur in dToF systems is pile-up effects, which may be more prominent in close-range returns. In greater detail, with higher emitter signal power, the return signals from nearby targets (or even highly reflective mid-range targets) can cause pileup effects at the detector level, where multiple photons may arrive at a detector close in time and thus the photon count indicated by the output detection signal may not be indicative of the actual conditions. This pileup may result in distortion of the detected pulse shape, and thus possible error in the ToF estimate.

In some embodiments of the present disclosure, the emitter signal power level may be increased or ramped up for respective subframes of the image frame. For example, in the example of FIG. 31B, the emitter elements may be operated to emit pulses with a lower peak power for the first 10,000 pulses/subframe than for the last 10,000 pulses/subframe 5. For example, the emitter pulse power for subframe 1 may be approximately 5% of the emitter pulse power for subframe 5. This allows for detection of close-range targets with less pile-up and detection of far range targets using higher optical power in each frame.

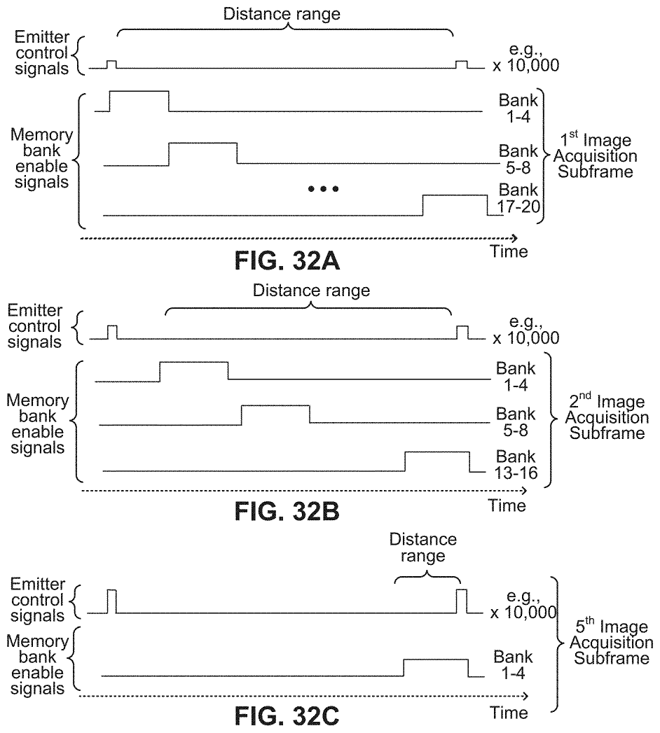

FIGS. 32A, 32B, and 32C illustrate example emitter control signals and memory bank enable signals that may be used to implement the operations of FIG. 31A. FIGS. 32A, 32B, and 32C also illustrate emitter control signals that are configured to provide stepped emitter power to reduce pile-up effects as discussed above. As shown in FIG. 32A, for the first 10,000 pulses of the image frame (subframe 1), all of the memory banks 1-20 are sequentially enabled (in groups or subsets of four memory banks) by the memory bank enable signals over the entire duration of time between emitter pulses (e.g., corresponding to the full 0-100 m distance range), such that all 20 memory banks record data for subframe 1. The emitter pulse power is also reduced to a relatively low power level for subframe 1, to reduce or avoid pileup effects from closer distance range targets.

In FIG. 32B, for the second 10,000 pulses of the image frame (subframe 2), memory banks 17-20 are not enabled, and the remaining memory banks 1-16 are sequentially enabled (in groups or subsets of four memory banks) by the memory bank enable signals over a portion of duration of time between emitter pulses (e.g., corresponding to a farther 20-100 m distance subrange), such that all 16 memory banks record data for subframe 2. The emitter pulse power is increased to a mid-power level for subframe 2, to ensure detection of mid-range targets.

As shown in FIG. 32C, for the last 10,000 pulses of the image frame (subframe 5), memory banks 5-20 are not enabled, and the remaining memory banks 1-4 are enabled (in a group or subset of four memory banks) by the memory bank enable signals over a portion of duration of time between emitter pulses (e.g., corresponding to the farthest 80-100 m distance subrange), such that only 4 memory banks record data for subframe 5. The emitter pulse power is increased to a relatively high power level for subframe 5, to ensure accurate detection of farther distance range targets.

As such, embodiments of the present invention may differently allocate memory banks to store photon counts for different distance subranges in each subframe. In the examples of FIGS. 31A and 32A to 32C, banks 1-4 store photon data for the 0-20 m subrange in subframe 1; for the 20-40 m subrange in subframe 2; for the 40-60 m subrange in subframe 3; for the 60-80 m subrange in subframe 4; and for the 80-100 m subrange in subframe 5. The emitter control signals and memory bank enable signals of FIGS. 32A-32C may be similarly applied (without varying the time bin allocation) to implement the operations of FIG. 31B. It will be understood that, while primarily described herein with reference to distance subranges that linearly vary with the respective subframes (e.g., covering a 20 m distance per subframe), in some embodiments the distance subranges that are imaged per subframe (and/or the number of emitter cycles per subframe) may vary non-linearly or otherwise non-equally among the subframes.

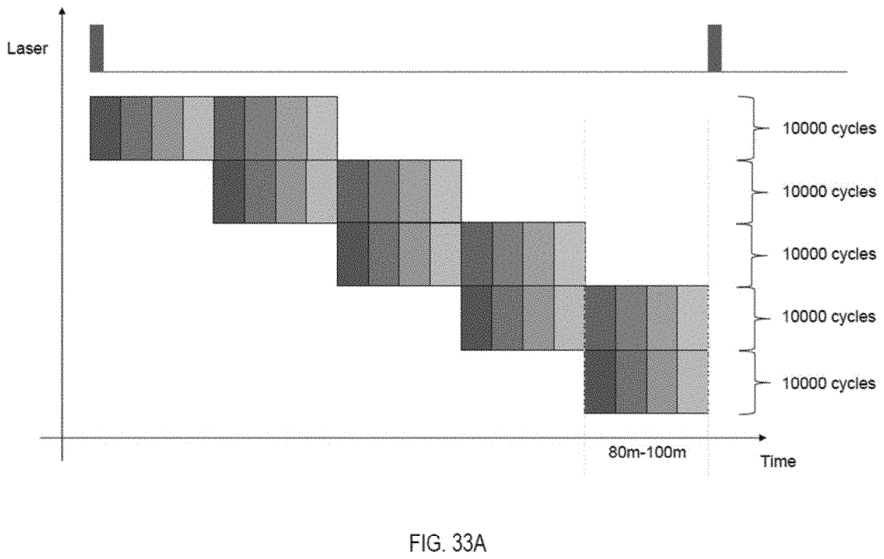

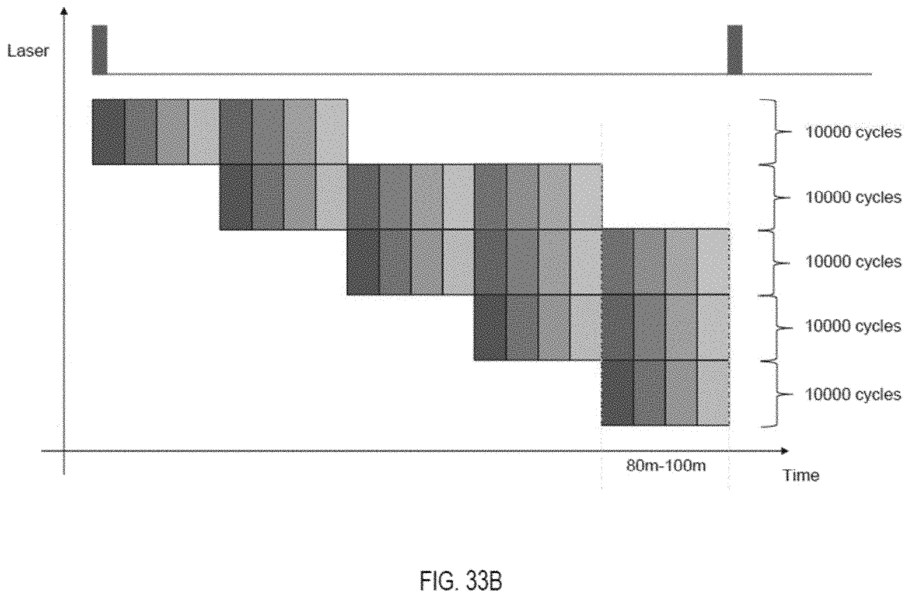

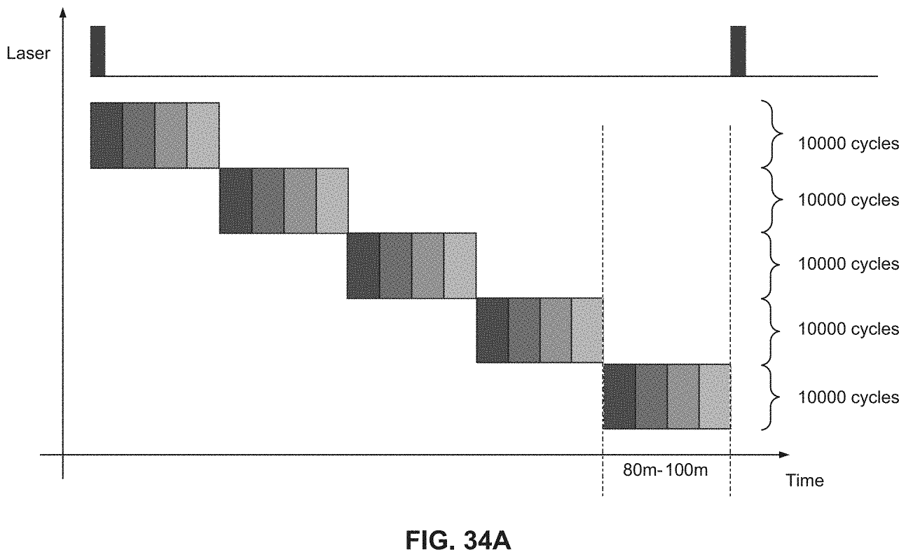

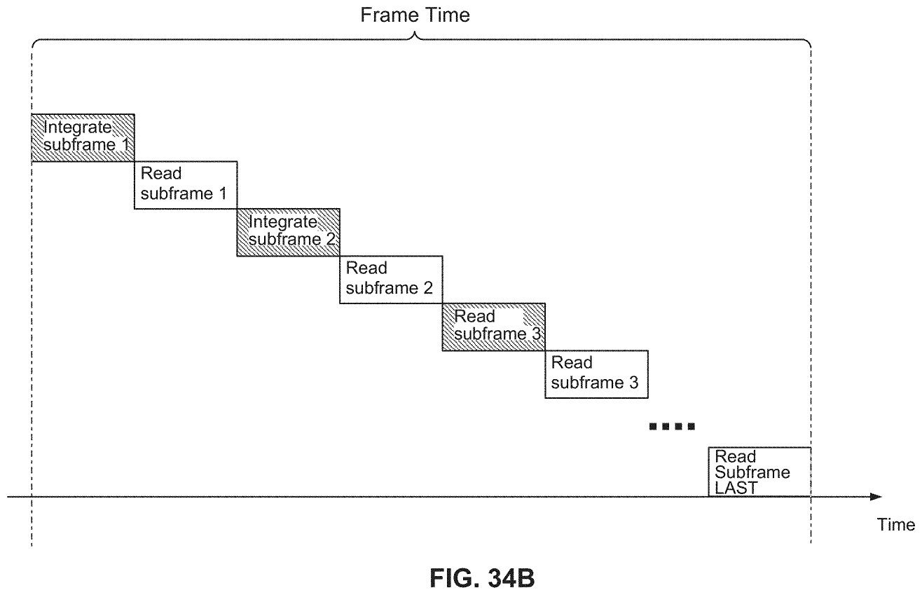

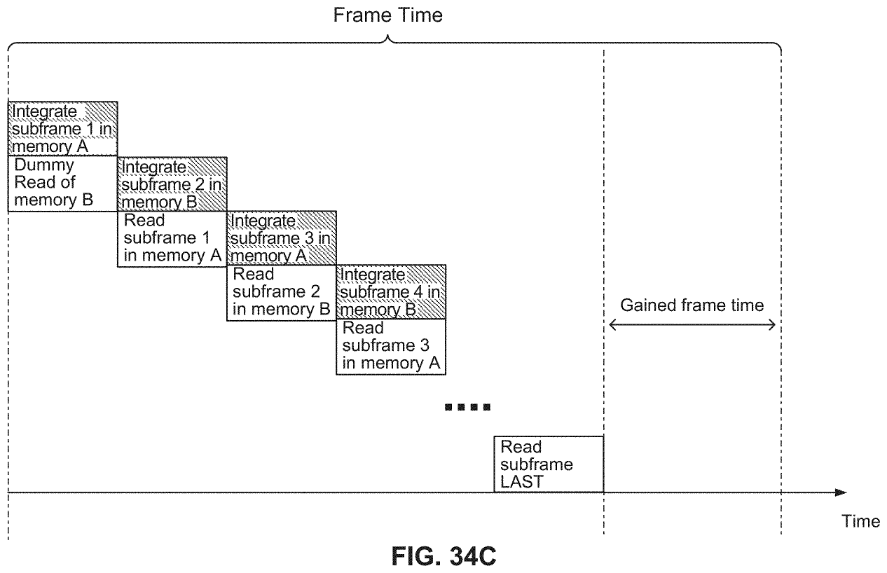

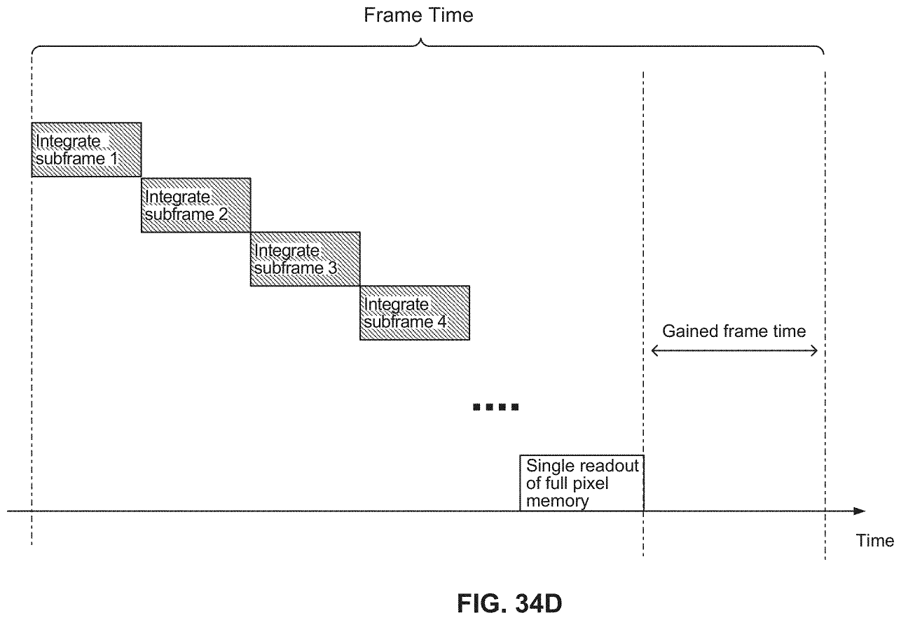

Further example embodiments are described below with reference to FIGS. 33A-33B and 34A-34D. As shown in the example of FIG. 33A, the bin allocation of the memory banks may be changed and subsets of the memory banks may be enabled for respective subframes such that subsections of bins are not activated throughout the full (e.g., 50,000 in this example) emitter cycles, which may be used to avoid integration of unnecessary background photons (which could negatively impact SNR). For example, the power level of the emitter during one or more subframes used to image closer distance subranges (e.g., for the first 30000 emitter cycles) may be insufficient for detection in the farther distance subranges (e.g., in embodiments where the emitter signal power level may be varied from lower power levels for closer distance subranges to higher power levels for farther distance subranges), such that photon count data accumulated for the bins corresponding to the farther (e.g., 80-100 m) distance subrange may mostly correspond to background light. As such, memory banks may be allocated to bins corresponding to the farther distance subranges only during the subframe(s) where higher emitter power levels are used (e.g., the last 20,000 emitter cycles only).

As shown in the example of FIG. 33B, the bin allocation of the memory banks may be changed and varying numbers of the memory banks may be enabled for respective subframes. That is, the example of FIG. 33B may be similar to the example of FIG. 33A, but with unequal effective integration time for different subsections of bins. For example, a first subsection of bins corresponding to a closer distance subrange (e.g., 0-20 m) may be integrated for 10,000 emitter cycles, second and third subsections of bins corresponding to mid-distance subranges (e.g., 20-40 m and 40-60 m) may be integrated for 20,000 emitter cycles, while fourth and fifth subsections of bins corresponding to farther distance subranges (e.g., 60-80 m and 80-100 m) may be integrated for 30,000 emitter cycles.

In the example of FIG. 34A, the bin allocation of the memory banks may be changed and subsets of the memory banks may be enabled for respective subframes such that subsections of bins corresponding to respective distance subranges may be integrated during emitter cycles with desired emitter power levels (e.g., in embodiments where the emitter signal power level may be varied from lower power levels for imaging closer distance subranges to higher power levels for imaging farther distance subranges). This may be similar or effectively equivalent to integrating multiple strobes before a readout operation at the end of a frame. The example of FIG. 34A may be used with a large memory bank in-pixel with flexible addressing, allowing for selection of subsections for integration.

FIG. 34B illustrates that readout intervals may consume a finite amount of time, which may reduce the frame time left for integrating laser cycles. That is, FIG. 34B illustrates that, in a given frame time, the many readout operations may take up a significant portion of the frame time. Having to readout every subframe may also increase the demand for effective frame rate of the sensor in order to meet the required ToF frame rate (i.e., more power).

FIG. 34C illustrates that two memory banks in pixel may be alternated in operation, allowing integration and readout simultaneously. This may increase or free up available frame time, which can be used for extending the integration time of the subframes and/or to perform postprocessing on the data as it is readout. However, such an implementation may require a larger and more complex pixel to accommodate both memory banks and their parallel operation and may also still require a higher effective frame rate in order to meet the ToF frame rate requirement.

In the example of FIG. 34D, a single readout at the end of a frame may provide an effective frame rate that is equal to a desired or required ToF frame rate. Such an implementation may increase or free up available frame time (which, as noted above, can be used for extending the integration time of the subframes and/or to perform postprocessing on the data as it is readout), and in addition may aid in meeting data transfer and processing latency of a lidar point cloud pipeline.

### 10. Example SPAD Detectors for a Sensor Array

In some embodiments described herein, pixels can include multiple different detector or sensor elements 142 (shown in FIG. 1) that can respond differently to incoming light, such that the response curves have different shapes and/or slopes. This allows one single acquisition to include both high response and low response elements, further extending the dynamic range of the acquisition.

In some embodiments, a pixel can include two or more differently sized detector components such that the different detector components gather photons with different rates.

For example, pixel detector components can be realized by tying (shorting) together multiple SPADs into groups of different sizes that all belong to the same pixel.

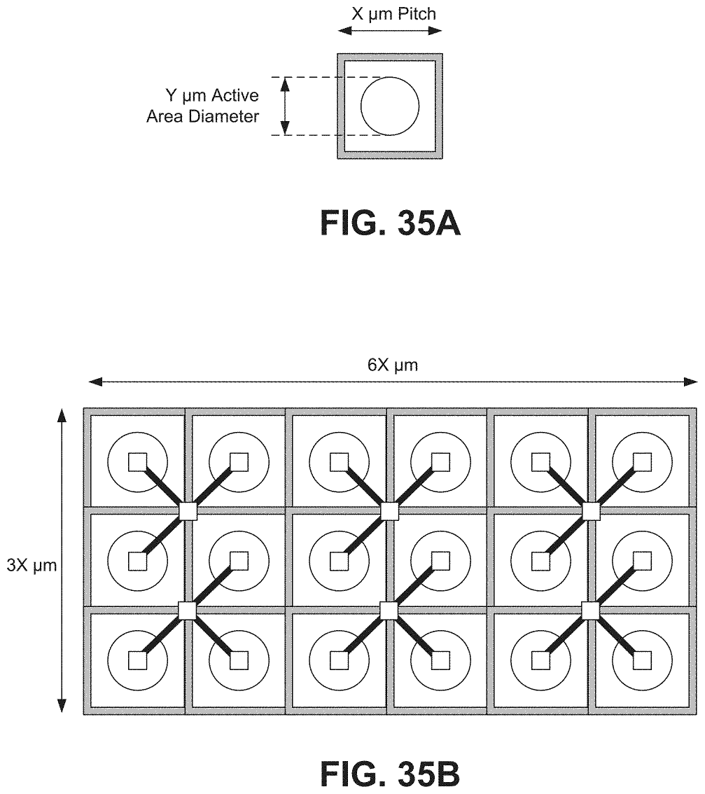

FIG. 35A is a simplified illustrate of an example SPAD that has a pitch of X microns pitch and a centrally located active area with a diameter of Y microns. As non-limiting examples, X can be 10, 15 or 20 microns and Y can be ½ X.

FIG. 35B illustrates an example of detector components for a pixel, where the detector components comprise SPADs. The six detector components can be formed of eighteen individual SPADs shown in FIG. 35A with each detector component built out of three SPADs tied together.

This same architecture could be used to tie together detector components of different sizes. For example, these eighteen SPADs could be grouped into three detector components having one SPAD, five SPADs and twelve SPADs, respectively, as shown in FIG. 36A. This would yield a detector with three ranges of sensitivity. One advantage of an approach that ties together multiple SPADs as compared to using different SPAD sizes is that different SPAD sizes have different breakdown voltages which can necessitate different high voltage supplies. Using groupings of a small SPAD structure can also improve device matching and help to maintain a desired range of sensitivity over manufacturing tolerances.

FIG. 36B illustrates another example of detector components for a pixel. In this example, the individual SPADs can be connected together to form detector components that include one, two, three, and four individual SPADs.

Some embodiments can be built using SPAD detectors. Other embodiments can use linear photodiodes. Other embodiments can use indirect time of flight pixels. Some embodiments can use detectors operating in the visible wavelength range, other embodiments can use detectors that operate in the infrared or ultraviolet wavelength range.

### 11. Multiple Lidar Units

Depending on their intended purpose or application, lidar sensors can be designed to meet different field of view (FOV) and different range requirements. For example, an automobile (e.g., a passenger car) outfitted with lidar for autonomous driving might be outfitted with multiple separate lidar sensors including a forward-facing long range lidar sensor, a rear-facing short-range lidar sensor and one or more short-range lidar sensors along each side of the car.

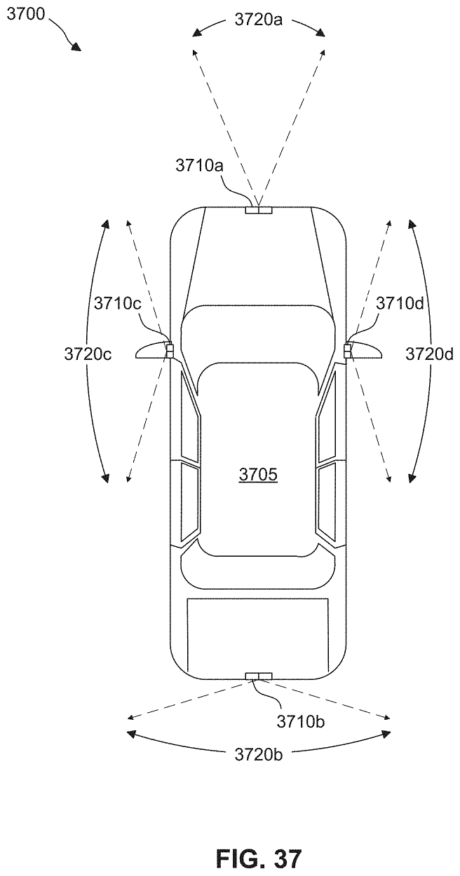

FIG. 37 is a simplified illustration of an automobile 3700 in which four solid-state flash lidar sensors 3710a-d are included at different locations along the automobile. The number of lidar sensors, the placement of the lidar sensors, and the fields of view of each individual lidar sensors can be chosen to obtain a majority of, if not the entirety of, a 360-degree field of view of the environment surrounding the vehicle some portions of which can be optimized for different ranges. For example, lidar sensor 3710a, which is shown in FIG. 37 as being positioned along the front bumper of automobile 3700, can be a long-range (200 meter), narrow field-of-view unit, while lidar sensors 3710b, positioned along the rear bumper, and lidar systems 3710c, 3710d, positioned at the side mirrors, are short-range (50 meter), wide field-of-view systems.

Despite being designed for different ranges and different fields of view, each of the lidar sensors 3710a-3210d can be a lidar system according to embodiments disclosed herein. Indeed, in some embodiments, the only difference between each of the lidar sensors 3710a-1910d is the properties of the diffuser (e.g., diffuser 136). For example, in long range, narrow field-of-view lidar sensor 3710a, the diffuser 136 is engineered to concentrate the light emitted by the emitter array of the lidar system over a relatively narrow range enabling the long-distance operation of the sensor. In the short-range, wide field-of-view lidar sensor 3710b, the diffuser 136 can be engineered to spread the light emitted by the emitter array over a wide angle (e.g., 180 degrees). In each of the lidar sensors 3710a and 3710b, the same emitter array, the same pixel array and the same controller, etc. can be used thus simplifying the manufacture of multiple different lidar sensors tailored for different purposes. Any or all of lidar sensors 3710a-3110d can incorporate the circuits, methods, and apparatus that can provide sensor arrays that are able to avoid or limit saturation of SPAD devices from both ambient and reflected light while maintaining sufficient sensitivity for generating a lidar image as described herein.

### 12. Additional Embodiments

In the above detailed description, numerous specific details are set forth to provide a thorough understanding of embodiments of the present disclosure. However, it will be understood by those skilled in the art that the present disclosure can be practiced without these specific details. For example, while various embodiments set forth above described can use different numbers of cycles and different power levels, these and other embodiments can use still other numbers of cycles and different power levels. Also, incident photons can be detected for various numbers of time bins that can extend to different time bins. As another example, some of the embodiments discussed above include a specific number of regions or diodes in a SPAD device. It is to be understood that those embodiments are for illustrative purposes only and embodiments are not limited to any particular number of regions or diodes in a SPAD device.

Additionally, in some instances, well-known methods, procedures, components, and circuits have not been described in detail so as not to obscure the present disclosure. It is intended that all embodiments disclosed herein can be implemented separately or combined in any way and/or combination. Aspects described with respect to one embodiment can be incorporated in different embodiments although not specifically described relative thereto. That is, all embodiments and/or features of any embodiments can be combined in any way and/or combination.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A lidar system comprising:
a plurality of emitter elements to emit optical signals;
a plurality of sensor elements to detect incident photons;
control circuitry to:
operate the plurality of emitter elements to emit a first optical signal having a first power level, and to operate the plurality of sensor elements to determine a number of detected incident photons during a first number of time bins, the first number of time bins beginning with an initial time bin and extending to a first time bin; and
operate the plurality of emitter elements to emit a second optical signal having a second power level, and to operate the plurality of sensor elements to determine a number of detected incident photons during a second number of time bins, the second number of time bins beginning with the initial time bin and extending to a second time bin,
wherein the second power level is a higher power level than the first power level and the second number is greater than the first number.

2. The lidar system of claim 1 wherein operating the plurality of emitter elements to emit a first optical signal having a first power level comprises operating the plurality of emitter elements to emit a first optical signal for a first number of cycles and operating sensor elements to determine a number of detected incident photons during a first number of time bins comprises operating sensor elements to determine a number of detected incident photons during a first number of time bins for each of the first number of cycles,
wherein operating the plurality of emitter elements to emit a second optical signal having a second power level comprises operating the plurality of emitter elements a to emit a second optical signal for a second number of cycles and operating sensor elements to determine a number of detected incident photons during a second number of time bins comprises operating sensor elements to determine a number of detected incident photons during a second number of time bins for each of the second number of cycles.

3. The lidar system of claim 2 wherein the second number of cycles is equal to the first number of cycles.

4. The lidar system of claim 2 wherein the second number of cycles is greater than the first number of cycles.

5. The lidar system of claim 1 wherein the control signal further operates the plurality of emitter elements to emit a third optical signal having a third power level, and to operate the sensor elements to determine a number of detected incident photons during a third number of time bins, the third number of time bins beginning with the initial time bin and extending to a third time bin,
wherein the third power level is a higher power level than the second power level and the third number is greater than the first number.

6. The lidar system of claim 1 further comprising:
generating a histogram by combining the number of incident photons detected in the first number of time bins following the emitted first optical signal and the number of incident photons detected in the second number of time bins following the emitted second optical signal.

7. The lidar system of claim 6 wherein combining the number of incident photons comprises summing the number of incident photons detected in the first number of time bins following the emitted first optical signal with the number of incident photons detected in the second number of time bins following the emitted second optical signal, and processing counts for the time bins beginning with the initial time bin and extending to the second time bin using a first algorithm, and processing counts for the time bins beginning with the time bin following the second time bin and extending to the first time bin using a second algorithm.

8. The lidar system of claim 7 wherein the first algorithm and the second algorithm compensate for a higher level of background information from the initial time bin to the second time bin.

9. The lidar system of claim 7 wherein the first algorithm and the second algorithm compensate for a difference between the first number of cycles and the second number of cycles.

10. The lidar system of claim 1 wherein each sensor element in the plurality of sensor elements comprises a plurality of groups of different number single-photon avalanche diodes connected in parallel.

11. A method of operating a lidar system, the method comprising:
operating a plurality of emitter elements to emit a first optical signal having a first power level, and operating a plurality of sensor elements to determine a number of detected incident photons during a first number of time bins, the first number of time bins beginning with an initial time bin and extending to a first time bin; and
operating the plurality of emitter elements to emit a second optical signal having a second power level, and operating the plurality of sensor elements to determine a number of detected incident photons during a second number of time bins, the second number of time bins beginning with the initial time bin and extending to a second time bin,
wherein the second power level is a higher power level than the first power level and the second number is greater than the first number.

12. The method of claim 11 wherein operating the plurality of emitter elements to emit a first optical signal having a first power level comprises operating the plurality of emitter elements a to emit a first optical signal for a first number of cycles and operating sensor elements to determine a number of detected incident photons during a first number of time bins comprises operating sensor elements to determine a number of detected incident photons during a first number of time bins for each of the first number of cycles,
wherein operating the plurality of emitter elements to emit a second optical signal having a second power level comprises operating the plurality of emitter elements a to emit a second optical signal for a second number of cycles and operating sensor elements to determine a number of detected incident photons during a second number of time bins comprises operating sensor elements to determine a number of detected incident photons during a second number of time bins for each of the second number of cycles.

13. The method of claim 12 wherein the second number of cycles is equal to the first number of cycles.

14. The method of claim 12 wherein the second number of cycles is greater than the first number of cycles.

15. The method of claim 11 further comprising operating the plurality of emitter elements to emit a third optical signal having a third power level, and operating the sensor elements to determine a number of detected incident photons during a third number of time bins, the third number of time bins beginning with the initial time bin and extending to a third time bin,
wherein the third power level is a higher power level than the second power level and the third number is greater than the first number.

16. The method of claim 11 further comprising:
generating a histogram by combining the number of incident photons detected in the first number of time bins following the emitted first optical signal and the number of incident photons detected in the second number of time bins following the emitted second optical signal.

17. The method of claim 16 wherein combining the number of incident photons comprises summing the number of incident photons detected in the first number of time bins following the emitted first optical signal with the number of incident photons detected in the second number of time bins following the emitted second optical signal, and processing counts for the time bins beginning with the initial time bin and extending to the second time bin using a first algorithm, and processing counts for the time bins beginning with the time bin following the second time bin and extending to the first time bin using a second algorithm.

18. The method of claim 17 wherein the first algorithm and the second algorithm compensate for a higher level of background information from the initial time bin to the second time bin.

19. The method of claim 17 wherein the first algorithm and the second algorithm compensate for a difference between the first number of cycles and the second number of cycles.

20. The method of claim 11 wherein each sensor element in the plurality of sensor elements comprises a plurality of groups of different number single-photon avalanche diodes connected in parallel.
